(19) United States
(12) Patent Application Publication
(10) Pub. No.: US 2007/0096100 A1
(43) Pub. Date: May 3, 2007

(54) Thin film transistors

(75) Inventors: Woo-Geun Lee, Yongin-si (KR); Jin-Ho Ju, Seoul (KR)

Correspondence Address: MACPHERSON KWOK CHEN & HEID LLP, 2033 GATEWAY PLACE, SUITE 400, SAN JOSE, CA, 95110, US

(73) Assignee: Samsung Electronics Co., Ltd.

(21) Appl. No.: 11/584,113

(22) Filed: Oct. 20, 2006

(30) Foreign Application Priority Data
Oct. 28, 2005 (KR) 10-2005-0102544

(51) Int. Cl. H01L 29/04; H01L 21/84

(52) U.S. Cl. 257/59; 257/72; 438/151; 257/E27.131

(57) ABSTRACT

A thin film transistor according to an embodiment of the present invention includes: a substrate; a control electrode disposed on the substrate; a gate insulating layer disposed on the control electrode; a semiconductor member disposed on the gate insulating layer, overlapping the control electrode, and including a first portion of amorphous silicon and a second portion of polycrystalline silicon; an input electrode contacting the semiconductor member; and an output electrode contacting the semiconductor member.

### CROSS-REFERENCE TO RELATED APPLICATION

This application claims priority to and the benefit of Korean patent application no. 10-2005-0102544 filed in the Korean intellectual property office on Oct. 28, 2005, the entire contents of which are incorporated herein by reference.

### FIELD OF THE INVENTION

The present invention relates to a thin film transistor, a display panel using the transistor, and a manufacturing method therefor.

### DESCRIPTION OF THE RELATED ART

Silicon is classified as amorphous or crystalline. Amorphous silicon can be deposited to form a thin film at a low temperature, and is widely used as the channel layer deposited on a low melting point glass substrate. However, thin film amorphous silicon has disadvantages such as a low field effect mobility and therefore has limited application for use in large display devices. Polycrystalline silicon having high field effect mobility, superior characteristics for high frequency operation and low leakage current is increasingly required for such an application.

A polysilicon thin film is usually formed by crystallizing amorphous silicon thin film using a laser beam and excimer laser annealing, sequential lateral solidification, etc.

However, the crystallization with a laser beam requires expensive equipment leading to high manufacturing costs. In addition, laser beam crystallization may not produce a uniform crystalline structure over the thin film.

### SUMMARY OF THE INVENTION

A thin film transistor according to an embodiment of the present invention includes: a substrate; a control electrode disposed on the substrate; a gate insulating layer disposed on the control electrode; a semiconductor member disposed on the gate insulating layer, overlapping the control electrode, and including a first portion of amorphous silicon and a second portion of polycrystalline silicon; an input electrode contacting the semiconductor member; and an output electrode contacting the semiconductor member.

The second portion of the semiconductor member may extend between the input electrode and the output electrode. The thin film transistor may further include a plurality of ohmic contacts interposed between the input electrode and the semiconductor member and between the output electrode and the semiconductor member and including amorphous silicon doped with impurity.

The second portion of the semiconductor member may include a sufficiently low amount of a conductive ingredient, for example, Al, Ni, or Au, which may be included in each of the input electrode and the output electrode.

Each of the input electrode and the output electrode may include a first metal film including Al, Ni, or Au, a second metal film disposed under the first metal film, and a third metal film disposed on the first metal film. The second and the third metal films may include at least one of Mo, Cr, Ta, Ti, and alloys thereof.

A display panel according to an embodiment of the present invention includes: a substrate; a scanning line disposed on the substrate and including a first control electrode; a gate insulating layer disposed on the scanning line; a first semiconductor member disposed on the gate insulating layer and including a first portion of amorphous silicon and a second portion of polycrystalline silicon; a data line contacting the first semiconductor member; a first output electrode separated from the data line and contacting the first semiconductor member; a passivation layer disposed on the first semiconductor member; and a pixel electrode disposed on the passivation layer.

The second portion of the first semiconductor member may extend between the data line and the first output electrode. The display panel may further include a plurality of ohmic contacts interposed between the data line and the first semiconductor member and between the first output electrode and the first semiconductor member and including amorphous silicon doped with impurity.

Each of the data line and the first output electrode may include a first metal film including Al, Ni, or Au, a second metal film disposed under the first metal film, and a third metal film disposed on the first metal film. The second and the third metal films may include at least one of Mo, Cr, Ta, Ti, and alloys thereof.

The first portion of the first semiconductor member may have substantially the same shape as the data line and the first output electrode.

The first output electrode may be connected to the pixel electrode.

The display panel may further include: a second control electrode disposed on the substrate; a second semiconductor member disposed on the gate insulating layer, overlapping the second control electrode, and including a first portion of amorphous silicon and a second portion of polycrystalline silicon; a driving voltage line contacting the second semiconductor member; a second output electrode contacting the second semiconductor member and connected to the pixel electrode; and an organic light emitting member disposed on the pixel electrode. The first output electrode and the second control electrode may be electrically coupled to each other.

A method of manufacturing a thin film transistor according to an embodiment of the present invention includes: forming a control electrode on a substrate; forming a gate insulating layer on the control electrode; sequentially forming an intrinsic semiconductor member and an extrinsic semiconductor member on the gate insulating layer; depositing a conductive layer on the extrinsic semiconductor member and the gate insulating layer; forming a photoresist on the conductive layer; etching the conductive layer and the extrinsic semiconductor member by using the photoresist as an etch mask to form an input electrode, an output electrode, and ohmic contacts and to expose a portions of the intrinsic semiconductor member; removing the photoresist by a stripper to form a metal thin film on the exposed portion of the semiconductor member; and annealing the substrate to crystallize the exposed portion of the semiconductor member.

The conductive layer may include a material that is soluble into the stripper for the photoresist, and the metal thin film may be formed by deposition of material dissolved from the conductive layer by the stripper.

The conductive layer may include a material that can serve as a seed for the crystallization, or the crystallization may include metal induced crystallization with a seed of the metal thin film.

The annealing may be performed at about 130-400° C.

The conductive layer may include a first metal film including Al, Ni, or Au, a second metal film disposed under the first metal film, and a third metal film disposed on the first metal film. The second and the third metal films may include at least one of Mo, Cr, Ta, Ti, and alloys thereof.

The stripper may include butyl diglycol (or diethylene glycol monobutyl ether), diethylene glycol monoethyl ether, dimethyl sulfoxide, N-methylpyrrolidone, and monoisopropanolamine.

### BRIEF DESCRIPTION OF THE DRAWINGS

The present invention will become more apparent from a reading of the ensuing description together with the drawing, in which:

FIG. 1 is a block diagram of an LCD according to an embodiment of the present invention;

FIG. 2A is an equivalent circuit diagram of a pixel of an LCD according to an embodiment of the present invention;

FIG. 2B is an equivalent circuit diagram of a pixel of an OLED display according to an embodiment of the present invention;

FIG. 3 is a layout view near a pixel electrode of a TFT array panel for a liquid crystal display according to an embodiment of the present invention;

FIG. 4 is a sectional view of the TFT array panel shown in FIG. 3 taken along the line IV-IV;

FIG. 5 is a layout view of a TFT in a scanning driver in the TFT array panel shown in FIG. 1 according to an embodiment of the present invention;

FIG. 6 is a sectional view of the TFT shown in FIG. 5 taken along the line VI-VI;

FIGS. 7 and 9 are layout views of the TFT array panel shown in FIGS. 3-6 in the first step of a manufacturing method thereof according to an embodiment of the present invention;

FIGS. 8 and 10 are sectional views of the TFT array panel shown in FIGS. 7 and 9 taken along lines VIII-VIII and X-X, respectively;

FIGS. 11 and 13 are layout views of the TFT array panel shown in FIGS. 3-6 in a step following the step shown in FIGS. 7-10;

FIGS. 12 and 14 are sectional views of the TFT array panel shown in FIGS. 11 and 13 taken along lines XII-XII and XIV-XIV, respectively;

FIGS. 15 and 17 are layout views of the TFT array panel shown in FIGS. 3-6 in a step following the step shown in FIGS. 11-14;

FIGS. 16 and 18 are sectional views of the TFT array panel shown in

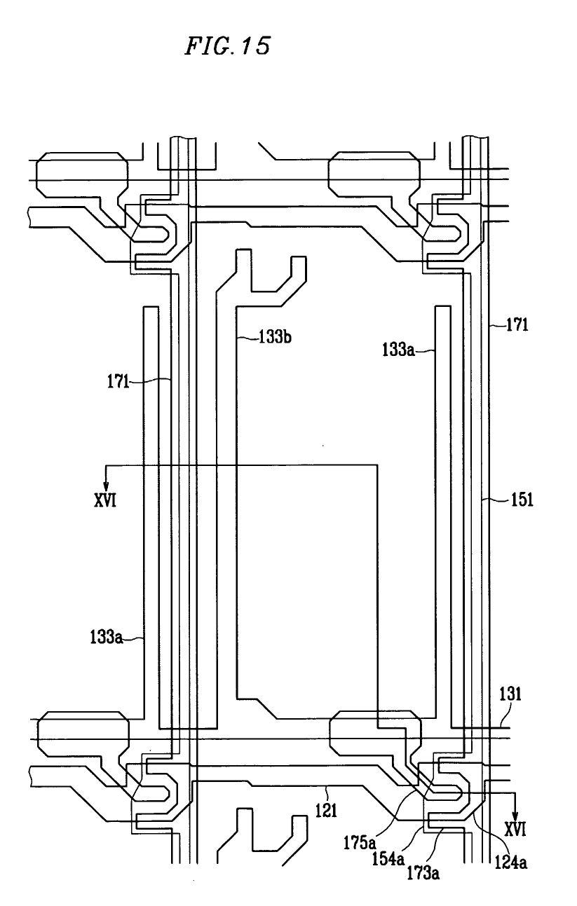

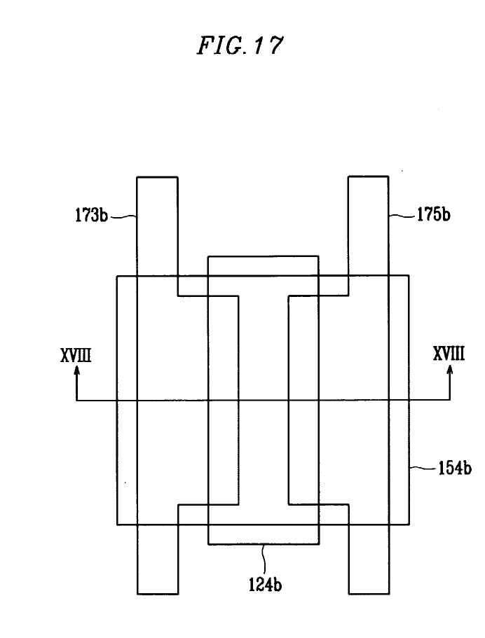

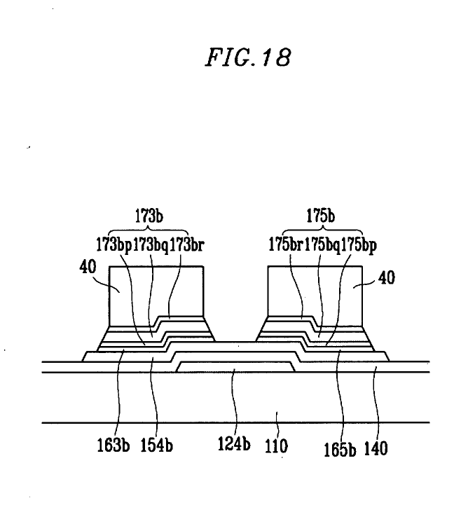

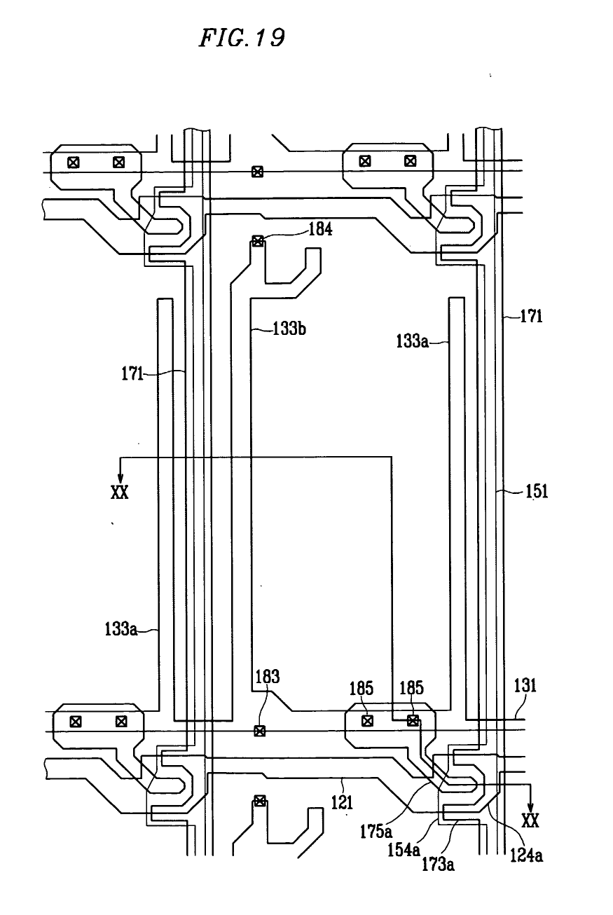

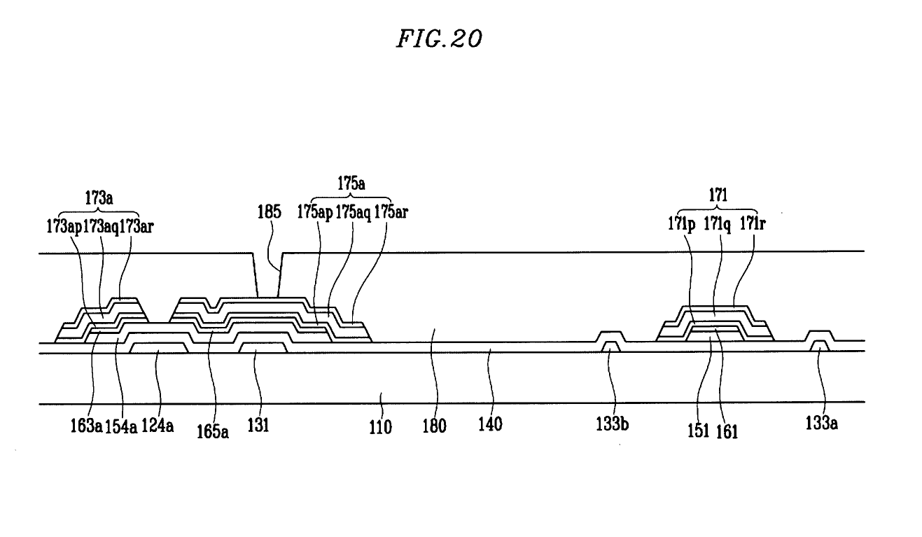

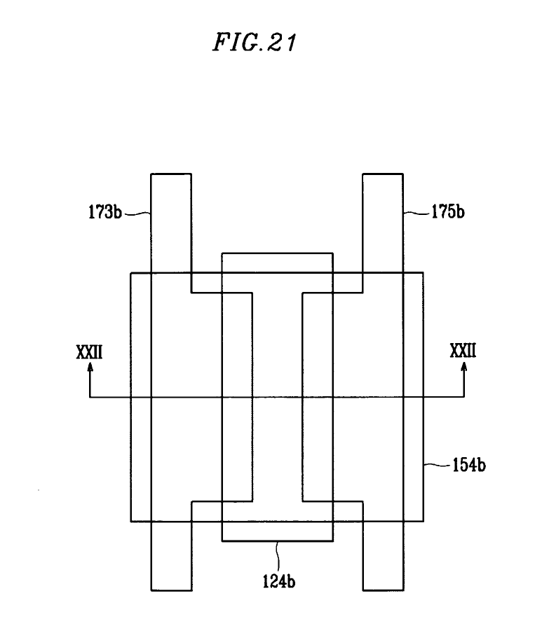

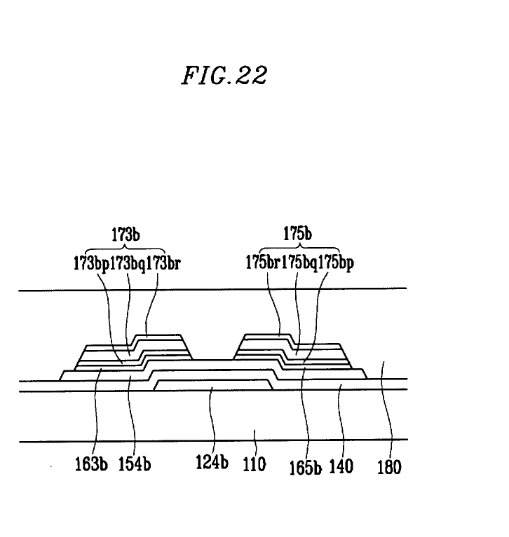

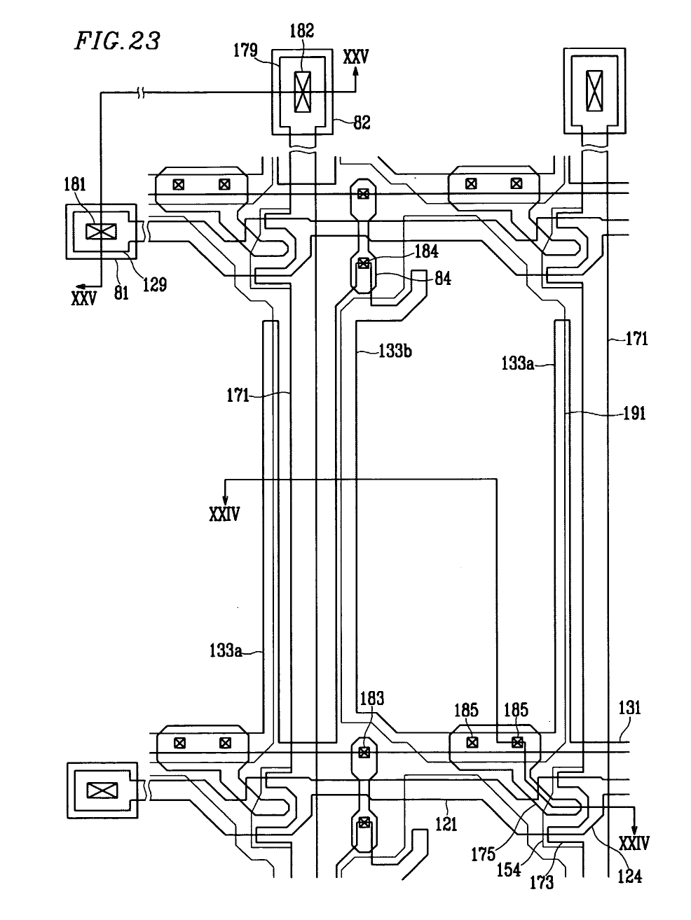

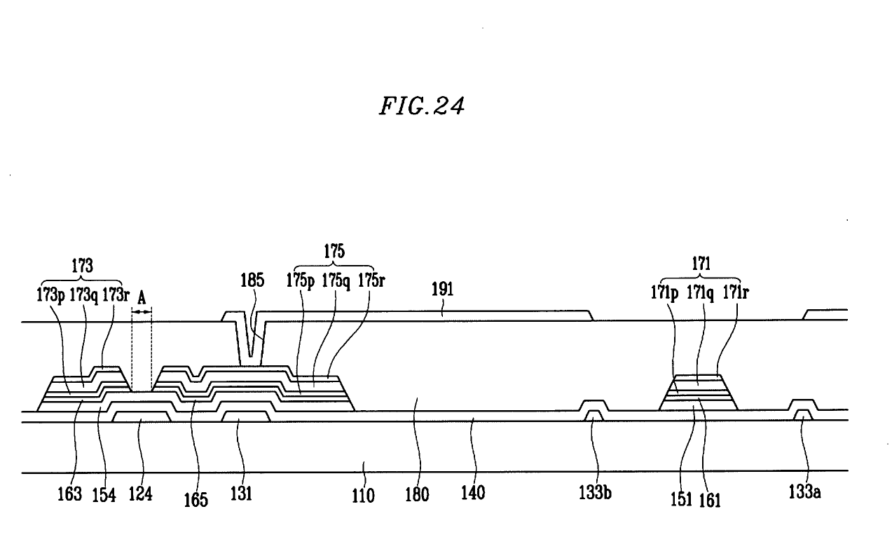

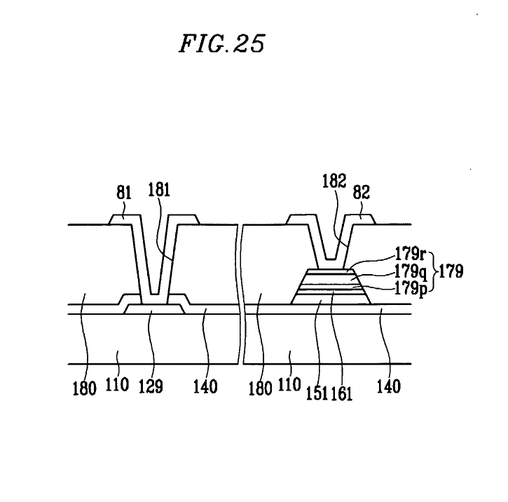

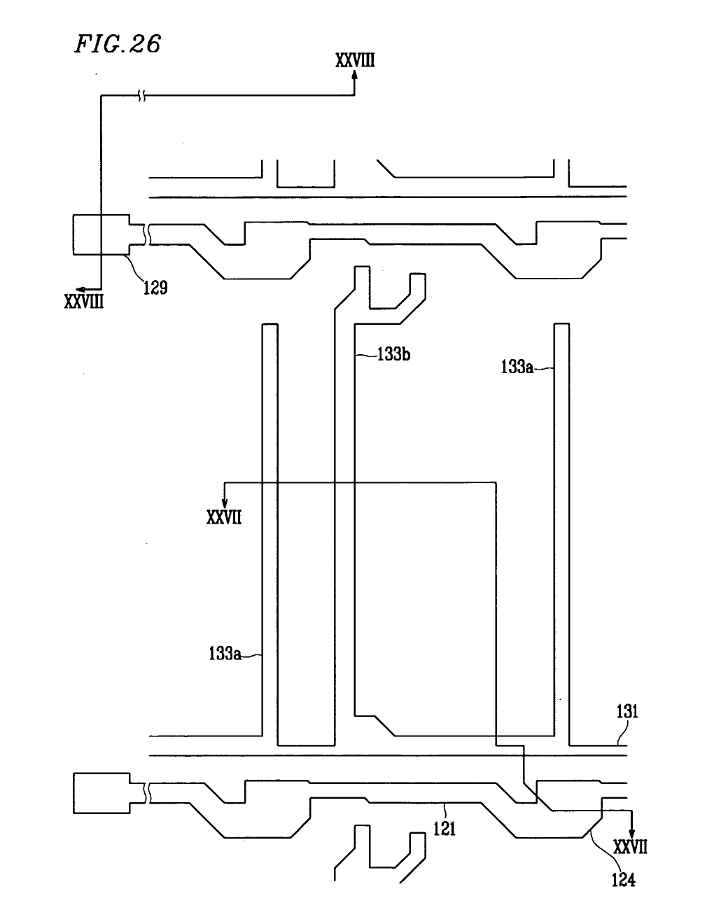

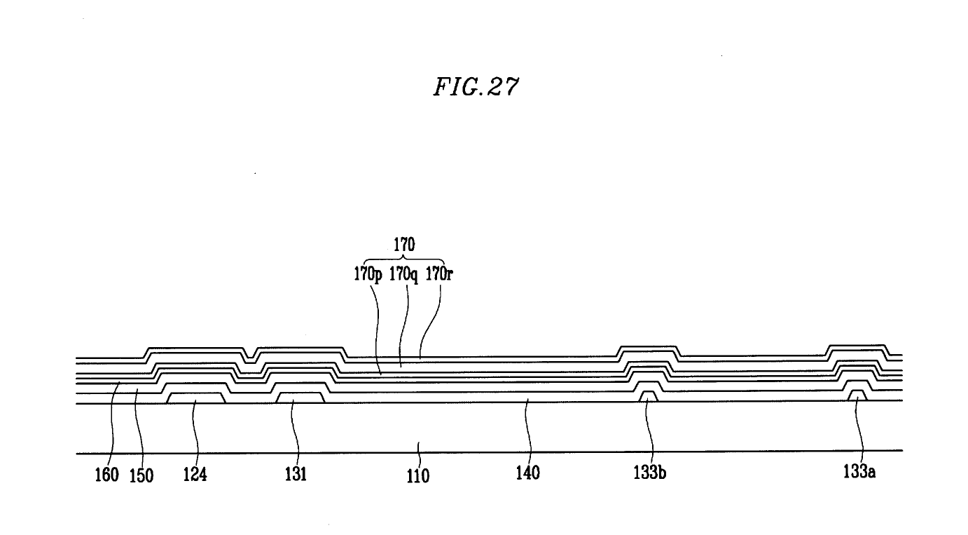

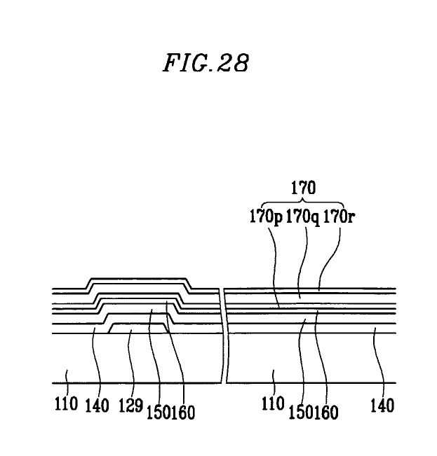

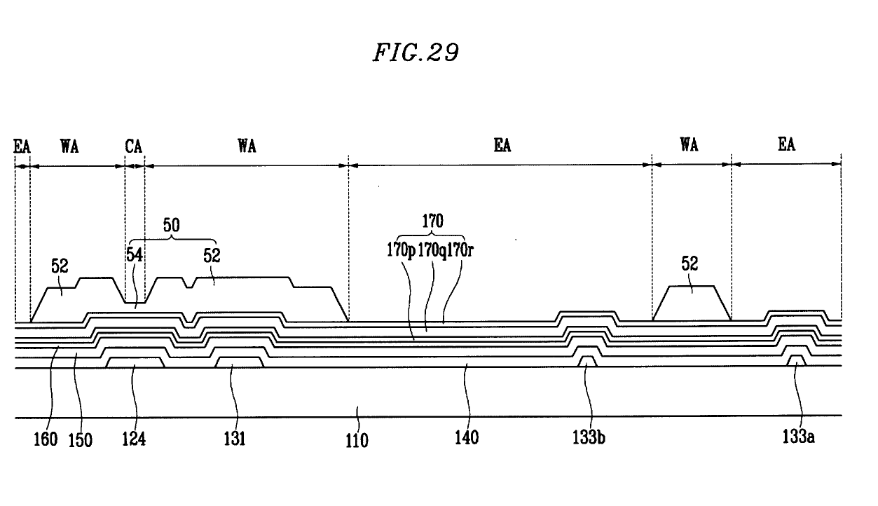

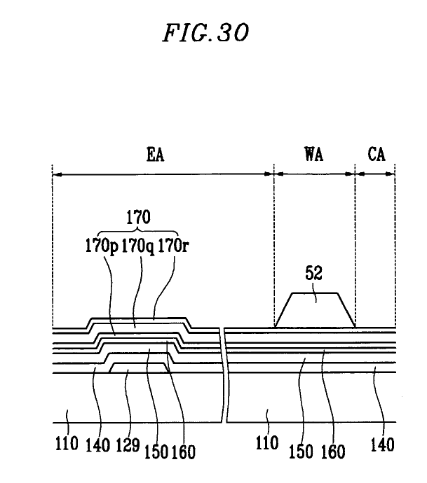

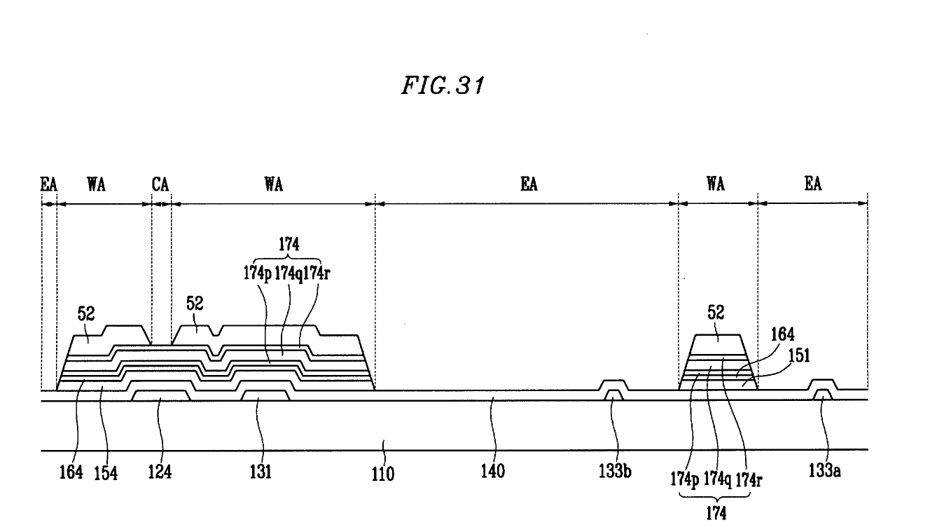

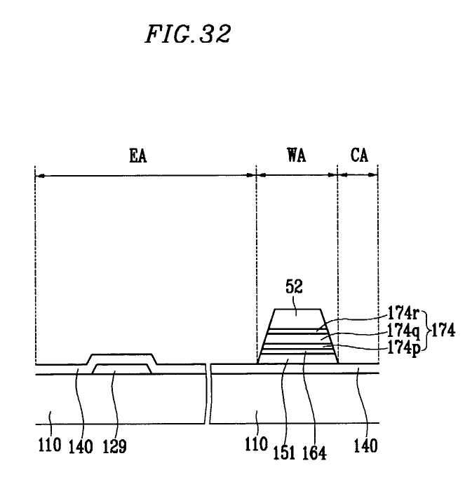

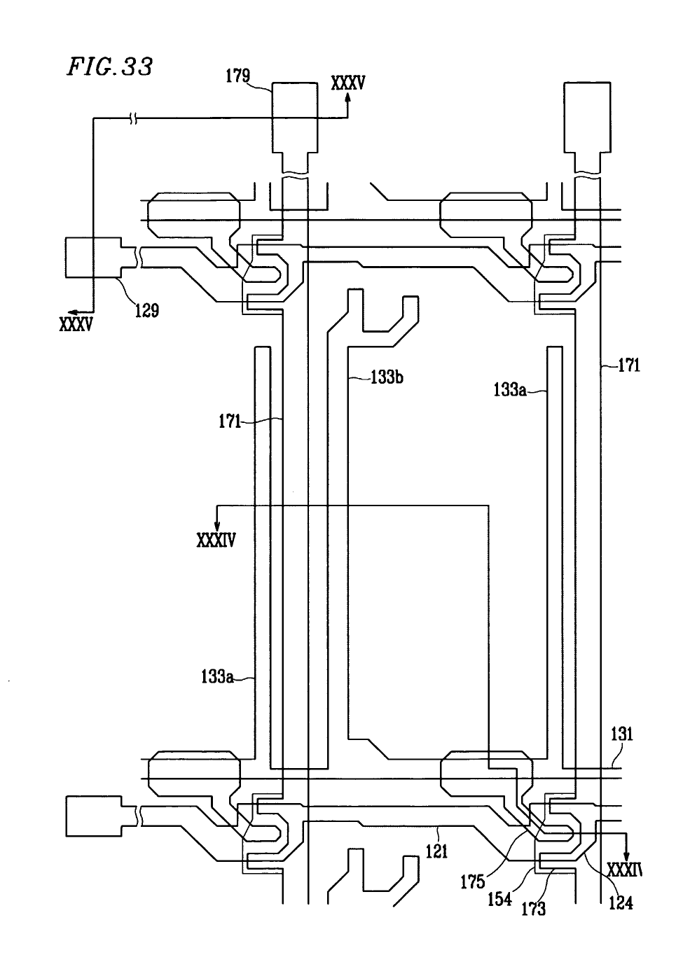

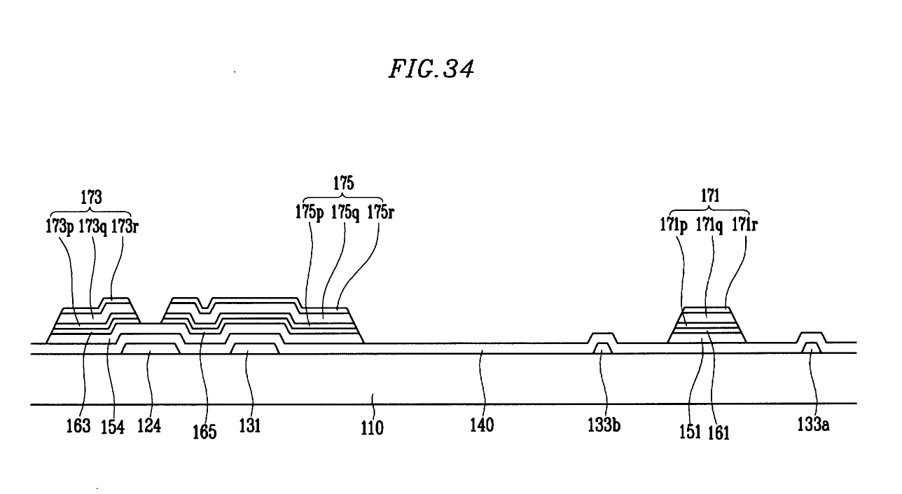

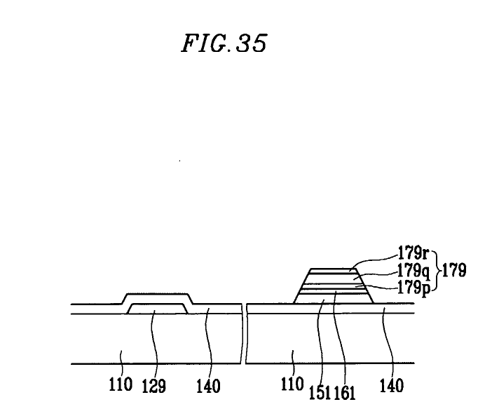

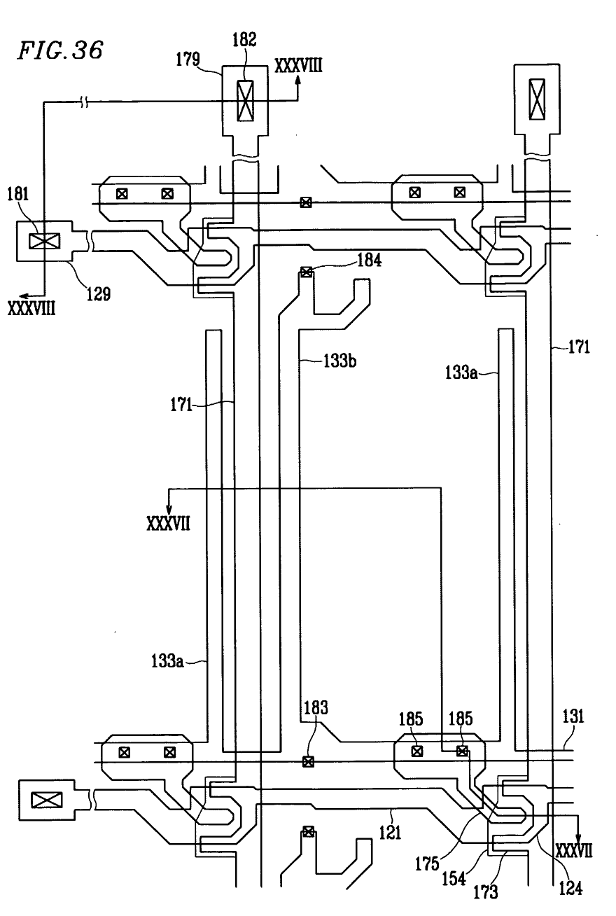

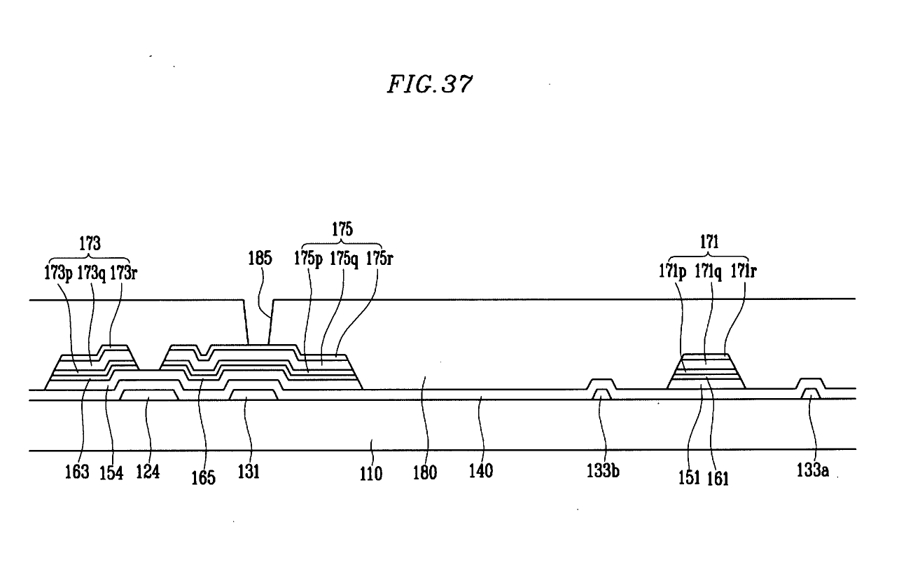

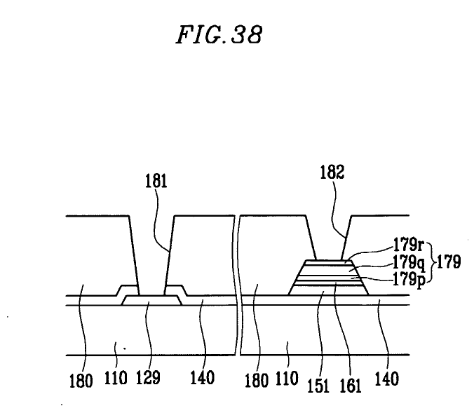

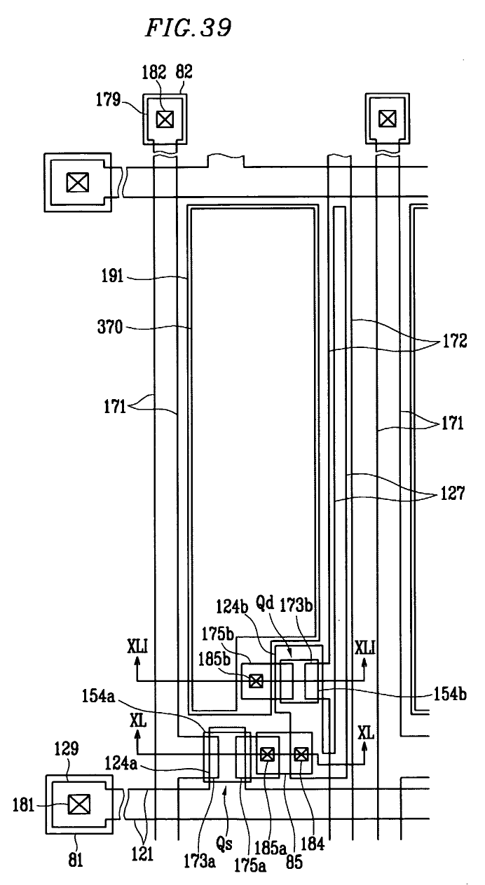

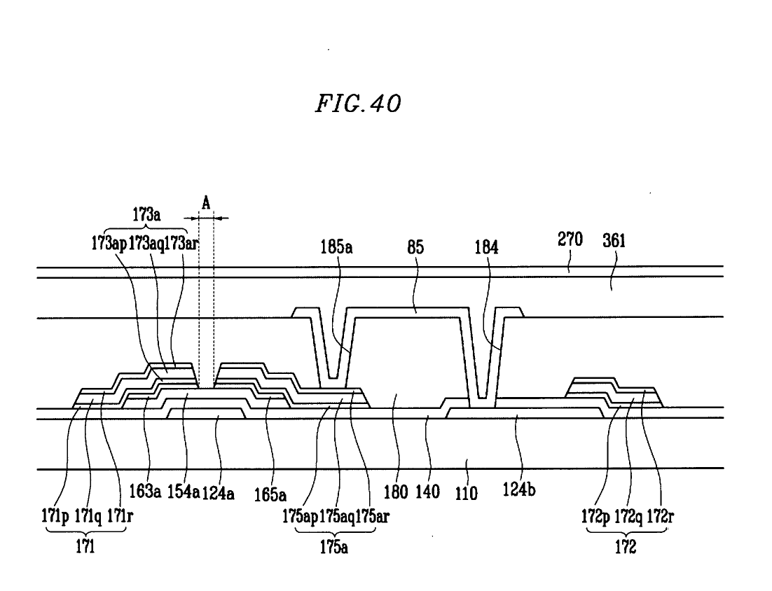

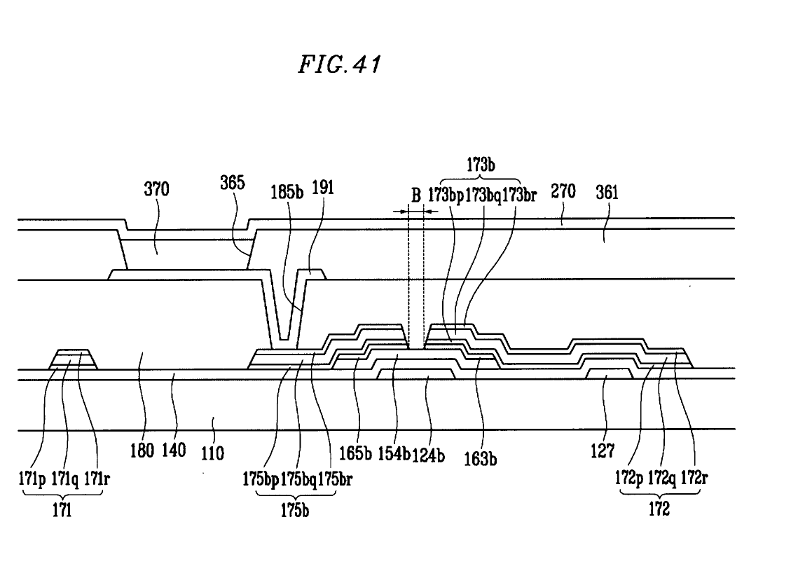

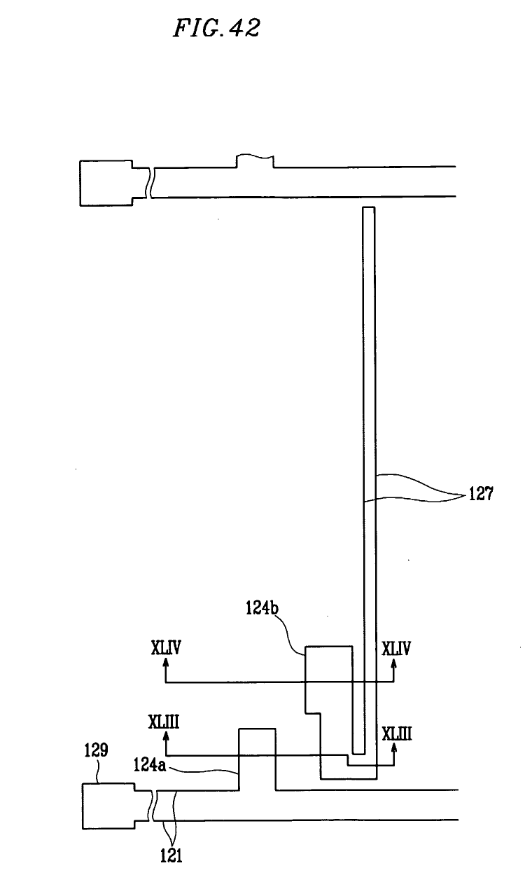

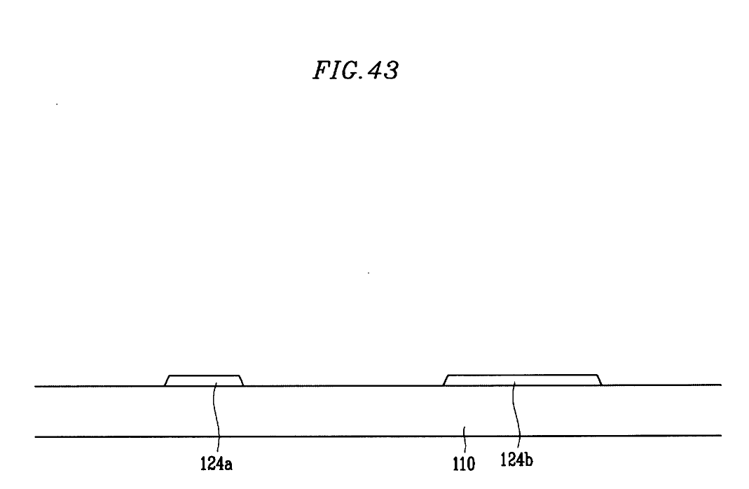

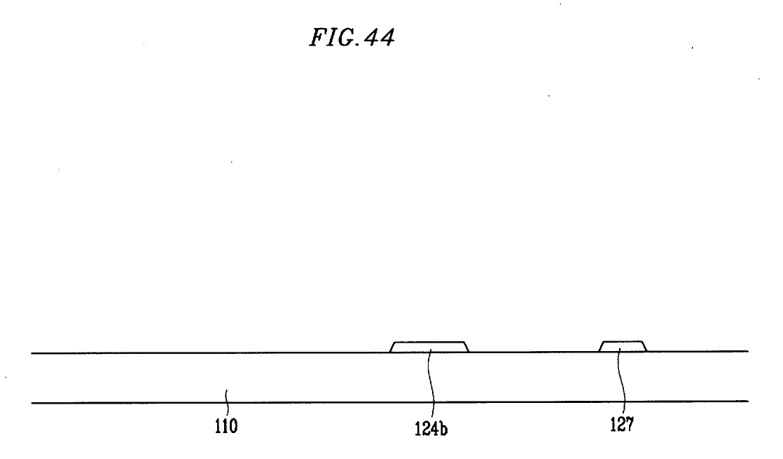

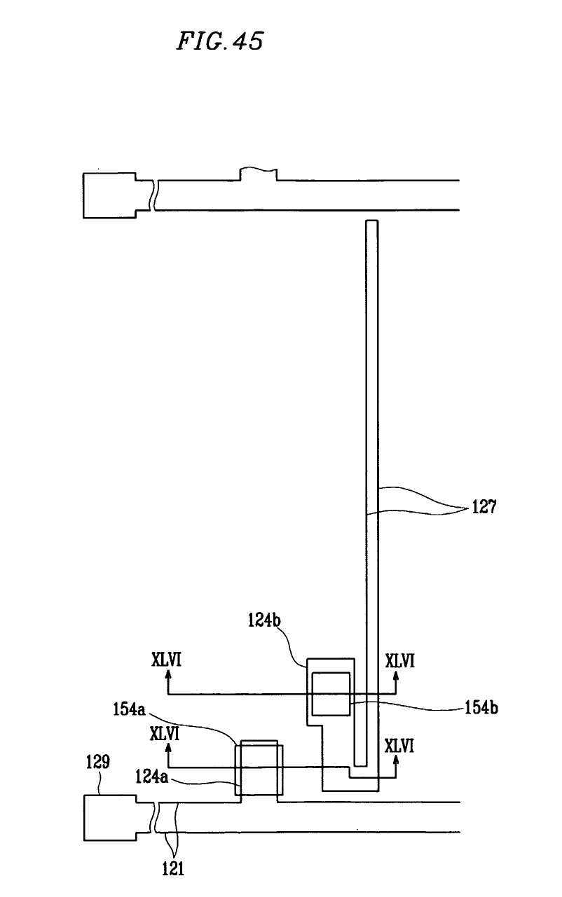

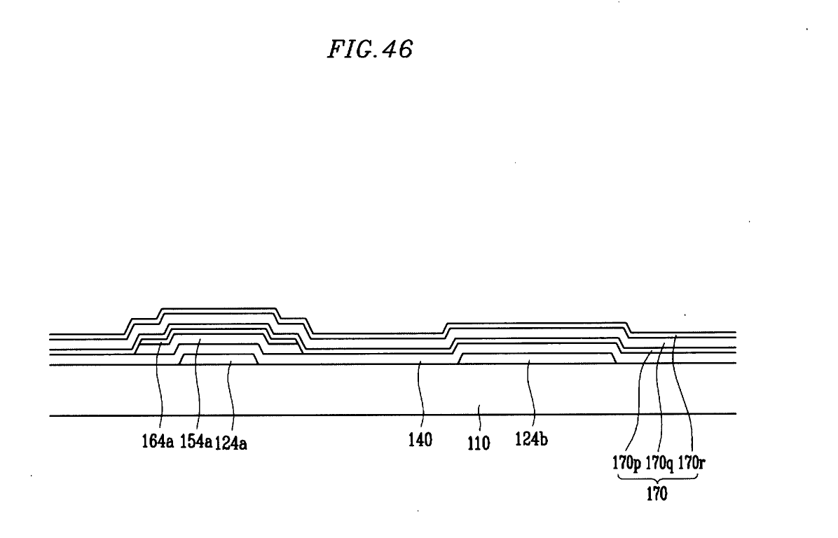

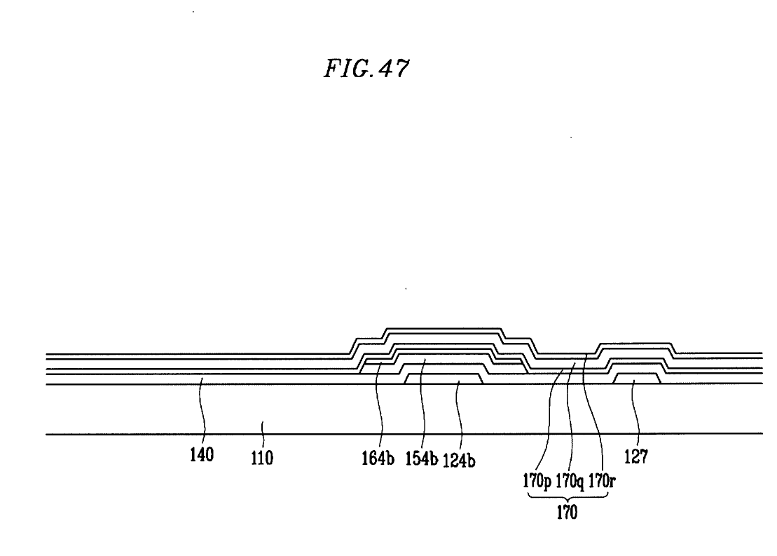

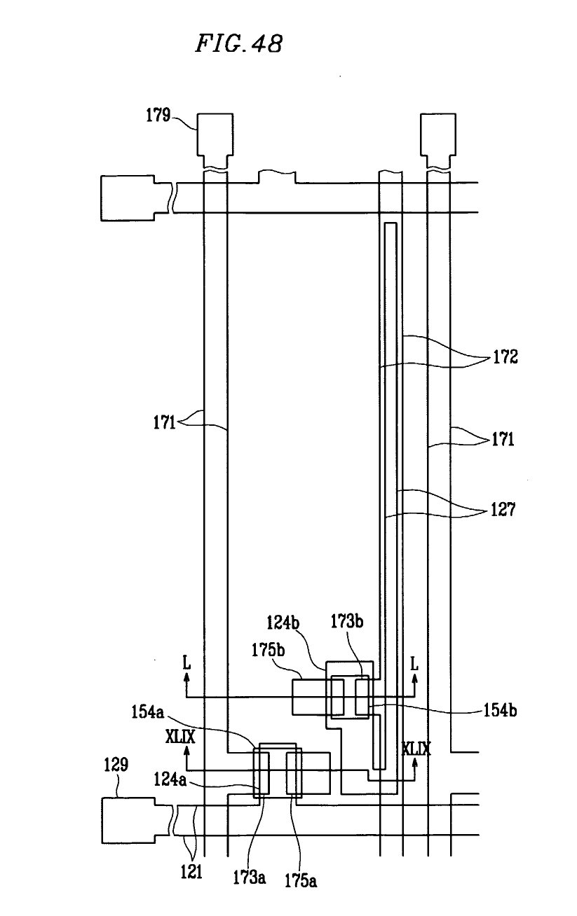

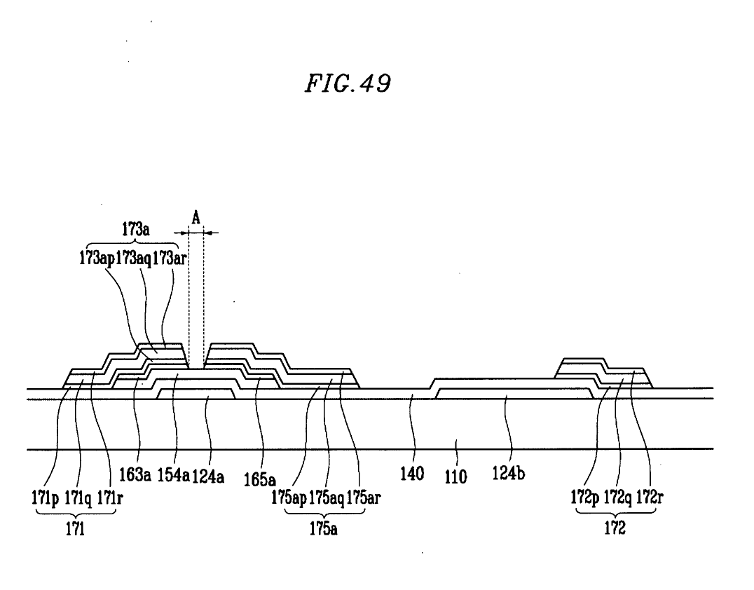

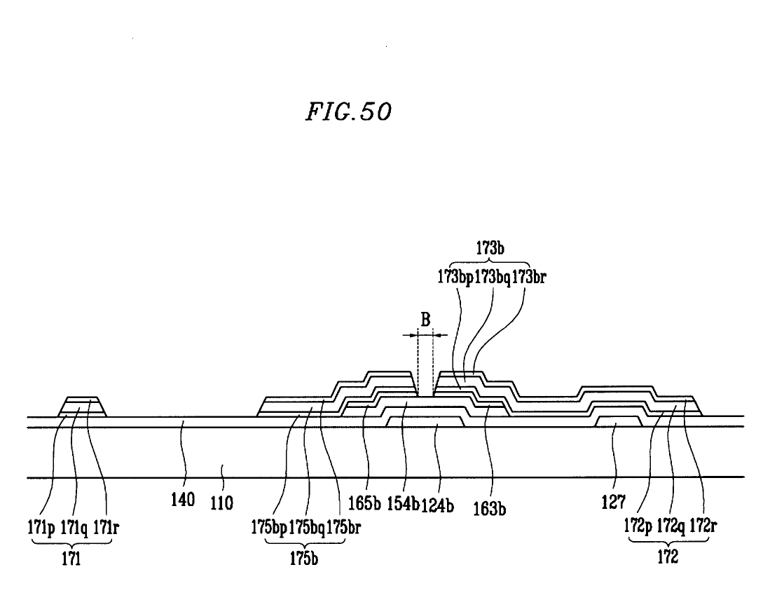

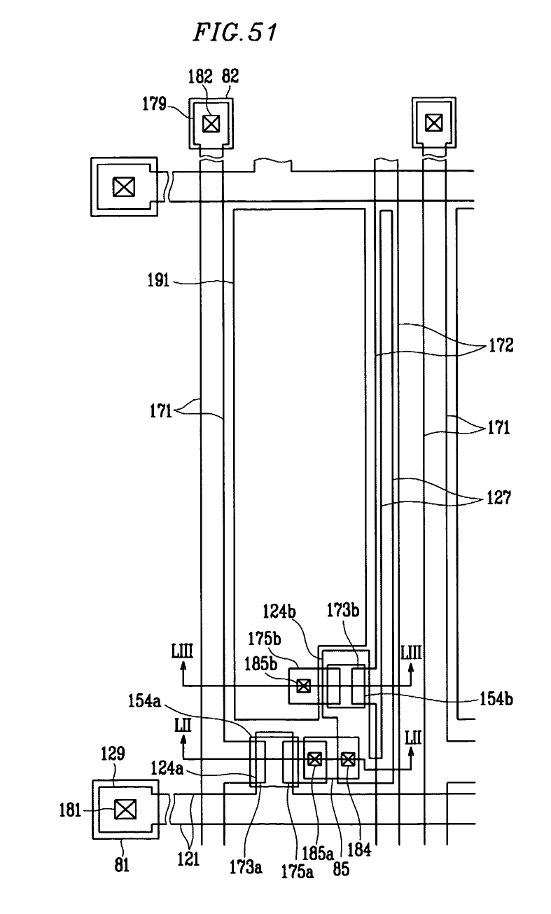

FIGS. 15 and 17 taken along lines XVI-XVI and XVIII-XVIII, respectively;

FIGS. 19 and 21 are layout views of the TFT array panel shown in FIGS. 3-6 in a step following the step shown in FIGS. 15-18;

FIGS. 20 and 22 are sectional views of the TFT array panel shown in FIGS. 19 and 21 taken along lines XX-XX and XXII-XXII, respectively;

FIG. 23 is a layout view of a TFT array panel according to another embodiment of the present invention;

FIGS. 24 and 25 are sectional views of the TFT array panel shown in FIG. 23 taken along lines XXIV-XXIV and XXV-XXV, respectively;

FIG. 26 is a layout view of the TFT array panel shown in FIGS. 23-25 in the first step of a manufacturing method thereof according to an embodiment of the present invention;

FIGS. 27 and 28 are sectional views of the TFT array panel shown in FIG. 26 taken along lines XXVII-XXVII and XXVIII-XXVIII, respectively;

FIGS. 29 and 30 are sectional views of the TFT array panel shown in FIG. 26 in a step following the step shown in FIGS. 27 and 28 taken along lines XXVII-XXVII and XXVIII-XXVIII, respectively;

FIGS. 31 and 32 are sectional views of the TFT array panel shown in FIG. 26 in a step following the step shown in FIGS. 29 and 30 taken along lines XXVII-XXVII and XXVIII-XXVIII, respectively;

FIG. 33 is a layout view of the TFT array panel shown FIGS. 23-25 in a step following the steps shown in FIGS. 26-32;

FIGS. 34 and 35 are sectional views of the TFT array panel shown in FIG. 33 taken along lines XXXIV-XXXIV and XXXV-XXXV, respectively;

FIG. 36 is a layout view of the TFT array panel shown FIGS. 23-25 in a step following the step shown in FIGS. 33-35;

FIGS. 37 and 38 are sectional views of the TFT array panel shown in FIG. 36 taken along lines XXXVII-XXXVII and XXXVIII-XXXVIII, respectively;

FIG. 39 is a layout view of a panel unit for an OLED display according to an embodiment of the present invention;

FIGS. 40 and 41 are sectional views of the panel unit shown in FIG. 39 taken along the lines XL-XL and XLI-XLI, respectively;

FIG. 42 is a layout view of the panel unit for an OLED display shown in FIGS. 39-41 in the first step of a manufacturing method thereof according to an embodiment of the present invention;

FIGS. 43 and 44 are sectional views of the panel unit shown in FIG. 42 taken along lines XLIII-XLIII and XLIV-XLIV, respectively;

FIG. 45 is a layout view of the panel unit shown in FIGS. 39-41 in a step following the step shown in FIGS. 42-44;

FIGS. 46 and 47 are sectional views of the panel unit shown in FIG. 45 taken along lines XLVI-XLVI and XLVII-XLVII, respectively;

FIG. 48 is a layout view of the panel unit shown in FIGS. 39-41 in a step following the step shown in FIGS. 45-47;

FIGS. 49 and 50 are sectional views of the panel unit shown in FIG. 48 taken along lines XLIX-XLIX and L-L, respectively;

FIG. 51 is a layout view of the panel unit shown in FIGS. 39-41 in a step following the step shown in FIGS. 15-18; and

FIGS. 52 and 53 are sectional views of the panel unit shown in FIG. 51 taken along lines LII-LII and LIII-LIII, respectively.

### DETAILED DESCRIPTION OF EMBODIMENTS

The present invention now will be described more fully hereinafter with reference to the accompanying drawings, in which preferred embodiments of the invention are shown.

In the drawings, the thickness of layers and regions are exaggerated for clarity. Like numerals refer to like elements throughout. It will be understood that when an element such as a layer, region or substrate is referred to as being “on” another element, it can be directly on the other element or intervening elements may also be present. In contrast, when an element is referred to as being “directly on” another element, there are no intervening elements present.

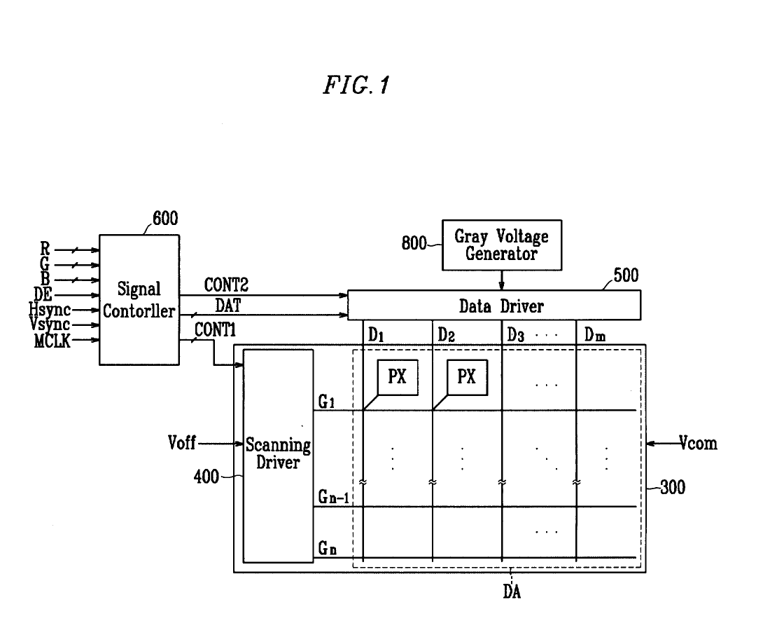

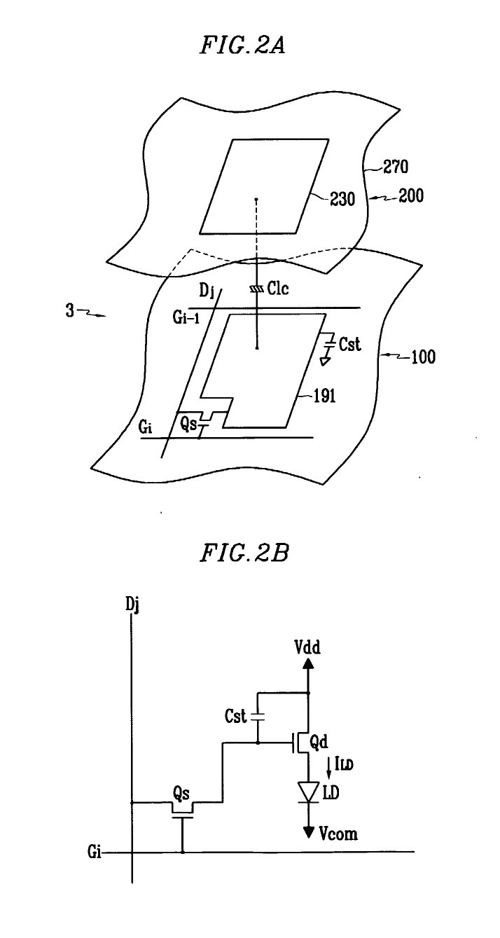

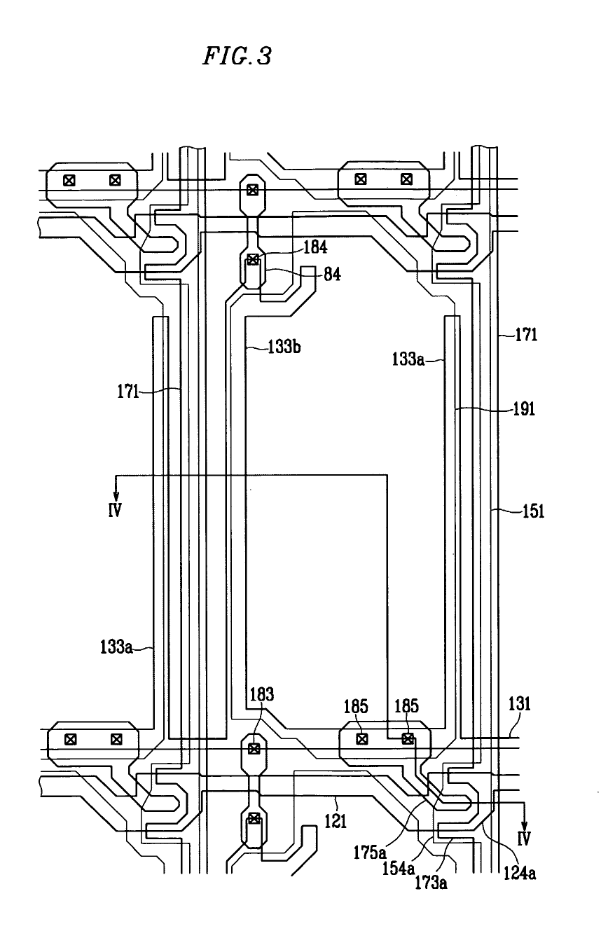

A display device according to an embodiment of the present invention now will be described in detail with reference to FIGS. 1, 2A and 2B.

FIG. 1 is a block diagram of a display device according to an embodiment of the present invention, FIG. 2A is an equivalent circuit diagram of a pixel of an LCD according to an embodiment of the present invention, and FIG. 2B is an equivalent circuit diagram of a pixel of an OLED display according to an embodiment of the present invention.

Referring to FIG. 1, a display device according to an embodiment includes a display panel unit 300, a scanning driver 400, a data driver 500, a gray voltage generator 800, and a signal controller 600. Panel unit 300 includes a plurality of signal lines G₁-Gₙ and D₁-Dₘ and a plurality of pixels PX connected to the signal lines G₁-Gₙ and D₁-Dₘ. Panel unit 300 for an LCD shown in FIG. 2A includes a lower panel 100, an upper panel facing the lower panel 100, and a LC layer 3 interposed between panels 100 and 200. As for an OLED display shown in FIG. 2B, the panel unit 300 may include only one panel (not shown).

The signal lines G₁-Gₙ and D₁-Dₘ are disposed in a display area DA of the panel unit 300, and extend out of the display area DA. The signal lines include a plurality of scanning lines G₁-Gₙ transmitting scanning signals (also referred to as “scanning signals” hereinafter) and a plurality of data lines D₁-Dₘ transmitting data voltages. Scanning lines G₁-Gₙ extend substantially in a row direction and substantially parallel to each other, while the data lines D₁-Dₘ extend substantially in a column direction and substantially parallel to each other.

The pixels PX are disposed in the display area DA and arranged substantially in a matrix. Each pixel PX includes at least one switching element (not shown) and at least one capacitor (not shown).

Referring to FIG. 2A, each pixel PX of the LCD, for example, a pixel PX connected to the i-th scanning line Gᵢ (i=1, 2, . . . , n) and the j-th data line Dⱼ (j=1, 2, . . . , m) includes a switching transistor Qs, a liquid crystal (LC) capacitor Clc, and a storage capacitor Cst. Storage capacitor Cst may be omitted.

Switching transistor Qs is disposed on the lower panel 100 and may be a thin film transistor (TFT). Switching transistor Qs has three terminals, i.e., a control terminal connected to the scanning line Gᵢ, an input terminal connected to the data line Dⱼ, and an output terminal connected to LC capacitor Clc and storage capacitor Cst.

LC capacitor Clc includes a pixel electrode 191 disposed on the lower panel 100 and a common electrode 270 disposed on the upper panel 200 as two terminals. LC layer 3 disposed between the two electrodes 191 and 270 functions as the dielectric of capacitor Clc. Pixel electrode 191 is coupled to switching transistor Qs, and the common electrode 270 is supplied with a common voltage Vcom and covers an entire surface of the upper panel 200. Unlike FIG. 2A, the common electrode 270 may be provided on the lower panel 100, and at least one of the electrodes 191 and 270 may have a shape of bar or stripe.

Storage capacitor Cst is an auxiliary capacitor for the LC capacitor Clc. Storage capacitor Cst includes pixel electrode 191 and a separate signal line, provided on the lower panel 100, that overlaps pixel electrode 191 and an insulating layer, is supplied with common voltage Vcom. Alternatively, storage capacitor Cst includes pixel electrode 191 and an adjacent scanning line Gᵢ₋₁ called a previous scanning line, which overlaps pixel electrode 191 and an insulating layer.

For color display, each pixel uniquely represents one of primary colors (i.e., spatial division) or each pixel sequentially represents the primary colors in turn (i.e., temporal division) such that spatial or temporal sum of the primary colors are recognized as a desired color. An example of a set of the primary colors includes red, green, and blue colors. FIG. 2A shows an example of the spatial division that each pixel includes a color filter 230 representing one of the primary colors in an area of the upper panel 200 facing pixel electrode 191. Alternatively, the color filter 230 is provided on or under pixel electrode 191 on the lower panel 100. One or more polarizers (not shown) are attached to the panel unit 300.

Referring to FIG. 2B which shows the equivalent circuit of an OLED, each pixel PX, for example, a pixel connected to a scanning line Gᵢ (i=1, 2, . . . n) and a data line Dⱼ includes an OLED LD, a driving transistor Qd, a capacitor Cst, and a switching transistor Qs.

Switching transistor Qs has a control terminal, an input terminal, and an output terminal. The control terminal of switching transistor Qs is connected to the scanning line Gᵢ, and the input terminal of switching transistor Qs is connected to the data line Dⱼ. The output terminal of switching transistor Qs is connected to a driving transistor Qd.

Driving transistor Qd also has a control terminal, an input terminal, and an output terminal. The control terminal of driving transistor Qd is connected to the output terminal of switching transistor Qs, and the input terminal of driving transistor Qd is connected to the driving voltage Vdd. The output terminal of driving transistor Qd is connected to the OLED LD.

The capacitor Cst is connected between the control terminal and the input terminal of driving transistor Qd.

The OLED LD has an anode connected to the output terminal of driving transistor Qd and a cathode connected to a common voltage Vcom.

Switching transistor Qs and driving transistor Qd are n-channel field effect transistors (FETs) including amorphous silicon or polysilicon. However, at least one of the transistors Qs and Qd may be p-channel FETs. The connection relationship among the transistors Qs and Qd, the capacitor Cst, and the OLED LD may be interchanged.

Referring to FIG. 1 again, the gray voltage generator 800 generates a full number of gray voltages or a limited number of gray voltages (referred to as “reference gray voltages” hereinafter) related to the luminance of the pixels PX. The gray voltage generator 800 for the LCD generates two sets of the (reference) gray voltages, and the (reference) gray voltages in one set have a positive polarity with respect to the common voltage Vcom, while those in the other set have a negative polarity with respect to the common voltage Vcom.

Scanning driver 400 is connected to scanning lines G₁-Gₙ of the panel unit 300 and synthesizes a high level voltage and a low level voltage Voff to generate the scanning signals for application to scanning lines G₁-Gₙ. Scanning driver 400 is incorporated into the panel unit 300 and disposed out of the display area DA. Scanning driver 400 includes a plurality of unit circuits (not shown). Each of the unit circuits is connected to one of scanning lines G₁-Gₙ and includes a plurality of TFTs. However, scanning driver 400 may include at least one integrated circuit (IC) chip mounted on the panel unit 300 or on a flexible printed circuit (FPC) film in a tape carrier package (TCP) type, which are attached to the panel unit 300.

Data driver 500 is connected to the data lines D₁-Dₘ of the panel unit 300 and applies data voltages, which are selected from the gray voltages supplied from the gray voltage generator 800, to the data lines D₁-Dₘ. However, when the gray voltage generator 800 generates only a limited number of the reference gray voltages other than all the gray voltages, data driver 500 may divide the reference gray voltages to generate the data voltages. Data driver 500 may be incorporated into the panel unit 300, or may include at least one integrated circuit (IC) chip mounted on the panel unit 300 or on a flexible printed circuit (FPC) film in a tape carrier package (TCP) type, which are attached to the panel unit 300. Data driver 500 is also disposed out of the display area DA.

Signal controller 600 controls scanning driver 400 and data driver 500, etc., and may be mounted on a printed circuit board (PCB) (not shown).

Now, the operation of the above-described display device will be described in detail.

Signal controller 600 is supplied with input image signals R, G and B and input control signals for controlling the display thereof from an external graphics controller (not shown). The input image signals R, G and B contain luminance information of pixels PX and the luminance has a predetermined number of grays, for example, 1024(=2¹⁰), 256(=2⁸), or 64(=2⁶) grays. The input control signals include a vertical synchronization signal Vsync, a horizontal synchronization signal Hsync, a main clock MCLK, and a data enable signal DE.

On the basis of the input control signals and the input image signals R, G and B, signal controller 600 generates scanning control signals CONT1 and data control signals CONT2 and it processes the image signals R, G and B suitable for the operation of the panel unit 300 and data driver 500. Signal controller 600 sends the scanning control signals CONT1 to scanning driver 400 and sends the processed image signals DAT and the data control signals CONT2 to data driver 500.

The scanning control signals CONT1 include a scanning start signal STV for instructing to start scanning and at least one clock signal for controlling the output period of the high level voltage. The scanning control signals CONT1 may include an output enable signal OE for defining the duration of the high level voltage.

The data control signals CONT2 include a horizontal synchronization start signal STH for informing of start of data transmission for a group of pixels PX, a load signal LOAD for instructing to apply the analog data voltages to the data lines D₁-Dₘ, and a data clock signal HCLK. The data control signal CONT2 for an LCD may further include an inversion signal RVS for reversing the polarity of the data voltages (relative to the common voltage Vcom).

Responsive to the data control signals CONT2 from signal controller 600, data driver 500 receives a packet of the digital image signals DAT for the group of pixels PX from signal controller 600, converts the digital image signals DAT into analog data voltages selected from the gray voltages, and applies the analog data voltages to the data lines D₁-Dₘ.

Scanning driver 400 applies a high level voltage to a scanning line G₁-Gₙ in response to the scanning control signals CONT1 from signal controller 600, thereby turning on the switching transistors Qs connected thereto. The data voltages applied to the data lines D₁-Dₘ are then supplied to the pixels PX through the activated switching transistors Qs.

In an LCD, the difference between a data voltage and the common voltage Vcom applied to a pixel PX is represented as a voltage across the LC capacitor Clc of the pixel PX, which is referred to as a pixel voltage. The LC molecules in the LC capacitor Clc have orientations depending on the magnitude of the pixel voltage, and the molecular orientations determine the polarization of light passing through the LC layer 3. The polarizer(s) converts the light polarization into the light transmittance such that the pixel PX has a luminance represented by a gray of an image signal DAT.

In an OLED display, a data voltage supplied for a pixel PX is applied to the control terminal of driving transistor Qd of the pixel PX, and driving transistor Qd drives an output current I_{LD} having a magnitude depending on the voltage between the control terminal and the output terminal thereof. The OLED LD of the pixel PX emits light having an intensity depending on the output current I_{LD} of driving transistor Qd such that the pixel PX has a luminance represented by a gray of an image signal DAT.

By repeating this procedure each horizontal period (also referred to as “1H” and equal to one period of the horizontal synchronization signal Hsync and the data enable signal DE), all scanning lines G₁-Gₙ are sequentially supplied with the high level voltage, thereby applying the data voltages to all pixels PX to display an image for a frame.

For an LCD, when the next frame starts after one frame finishes, the inversion control signal RVS applied to data driver 500 is controlled such that the polarity of the data voltages is reversed (which is referred to as “frame inversion”). The inversion control signal RVS may be also controlled such that the polarity of the data voltages flowing in a data line are periodically reversed during one frame (for example, row inversion and dot inversion), or the polarity of the data voltages in one packet are reversed (for example, column inversion and dot inversion).

Now, a lower panel, i.e., a TFT array panel for an LCD shown in FIG. 2A according to an embodiment of the present invention will be described in detail with reference to FIGS. 3, 4, 5 and 6.

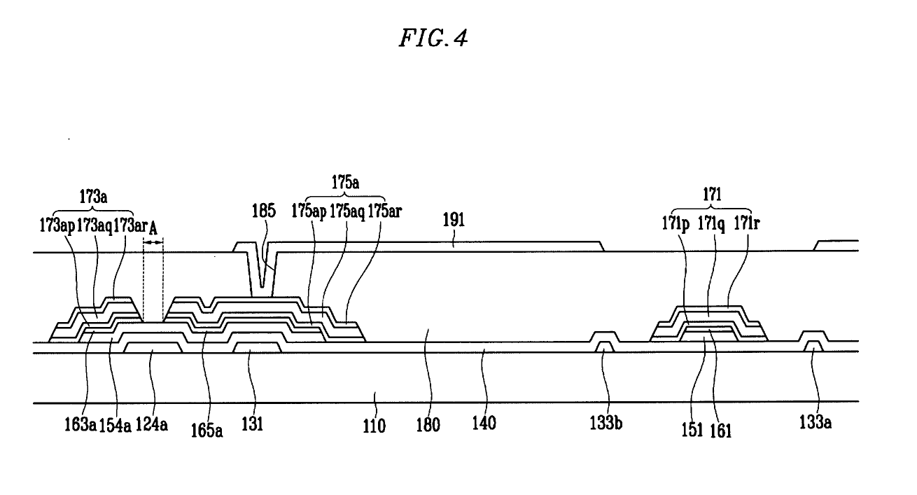

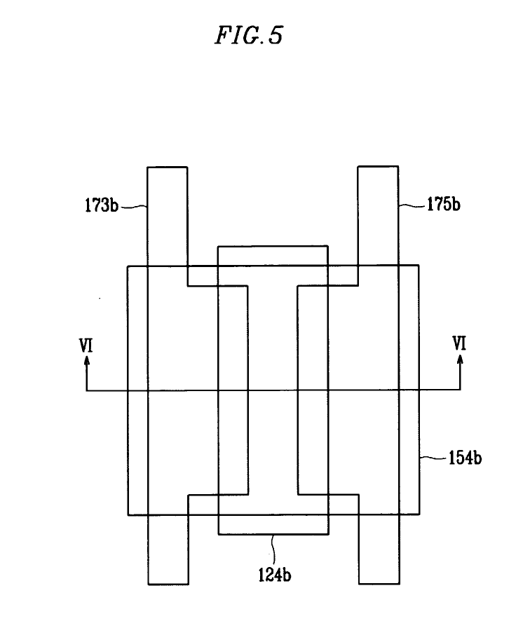

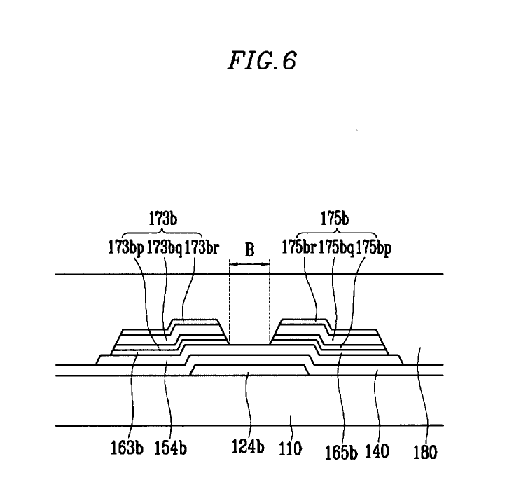

FIG. 3 is a layout view near a pixel electrode of a TFT array panel for a liquid crystal display according to an embodiment of the present invention, FIG. 4 is a sectional view of the TFT array panel shown in FIG. 3 taken along the line IV-IV, FIG. 5 is a layout view of a TFT in a scanning driver in the TFT array panel shown in FIG. 1 according to an embodiment of the present invention, and FIG. 6 is a sectional view of the TFT shown in FIG. 5 taken along the line VI-VI.

A plurality of gate conductors including a plurality of scanning lines 121 including first control electrodes 124a, a plurality of storage electrode lines 131, and a plurality of second control electrodes 124b are formed on an insulating substrate 110 such as transparent glass or plastic.

Scanning lines 121 transmit scanning signals and extend substantially in a transverse direction. An end of each of scanning lines 121 is connected to a scanning driver 400 and the first control electrodes 124a project downward.

The first control electrodes 124a project downward from scanning lines 121 and the second control electrodes 124b may be connected to signal lines (not shown) for applying control signals.

Storage electrode lines 131 are supplied with a predetermined voltage and each of storage electrode lines 131 includes a stem extending substantially parallel to scanning lines 121 and a plurality of pairs of first and second storage electrodes 133a and 133b branching from the stem. Each of storage electrode lines 131 is disposed between two adjacent scanning lines 121 and the stem is close to one of the two adjacent scanning lines 121. Each of the storage electrodes 133a and 133b has a fixed end portion connected to the stem and a free end portion disposed opposite thereto. The fixed end portion of the second storage electrode 133b has a large area and the free end portion thereof is bifurcated into a linear branch and a curved branch. However, storage electrode lines 131 may have various shapes and arrangements.

Gate conductors 121, 124b and 131 may be made of Al containing metal such as Al and Al alloy, Ag containing metal such as Ag and Ag alloy, Cu containing metal such as Cu and Cu alloy, Mo containing metal such as Mo and Mo alloy, Cr, Ta, or Ti. However, gate conductors 121, 124b and 131 may have a multi-layered structure including two conductive films (not shown) having different physical characteristics. One of the two films may be made of low resistivity metal including Al containing metal, Ag containing metal, and Cu containing metal for reducing signal delay or voltage drop. The other film may be made of material such as Mo containing metal, Cr, Ta, or Ti, which has good physical, chemical, and electrical contact characteristics with other materials such as indium tin oxide (ITO) or indium zinc oxide (IZO). Good examples of the combination of the two films are a lower Cr film and an upper Al (alloy) film and a lower Al (alloy) film and an upper Mo (alloy) film. However, gate conductors 121, 124b and 131 may be made of various metals or conductors.

The lateral sides of gate conductors 121, 124b and 131 are inclined relative to a surface of the substrate 110, and the inclination angle thereof ranges about 30-80 degrees.

A gate insulating layer 140 preferably made of silicon nitride (SiNx) or silicon oxide (SiOx) is formed on gate conductors 121, 124b and 131.

A plurality of semiconductor stripes 151 and a plurality of semiconductor islands 154b are formed on the gate insulating layer 140. Each of semiconductor stripes 151 extends substantially in the longitudinal direction and includes a plurality of projections 154a branching out toward the first control electrodes 124a. Semiconductor stripes 151 become wide near scanning lines 121 and storage electrode lines 131 such that semiconductor stripes 151 cover large areas of scanning lines 121 and storage electrode lines 131. Semiconductor islands 154b are disposed on the second control electrodes 124b.

Semiconductor stripes 151 and semiconductor islands 154b may be made of hydrogenated amorphous silicon (abbreviated to “a-Si”) except for portions denoted by reference character A in FIG. 4 and denoted by reference character B in FIG. 6, and the portions A and B may be made of polysilicon. The portions A and B may contain a sufficiently small amount of a conductor such as a metal.

A plurality of ohmic contact stripes and islands 161 and 165a are formed on semiconductor stripes 151, and a plurality of ohmic contact islands 163b and 165b are formed on semiconductor islands 154b. The ohmic contact stripes and islands 161, 163b, 165a and 165b are preferably made of n+ hydrogenated a-Si heavily doped with n type impurity such as phosphorous or they may be made of silicide. Each of the ohmic contact stripes 161 includes a plurality of projections 163a, and the projections 163a and the ohmic contact islands 165a are located in pairs on the projections 154a of semiconductor stripes 151.

The lateral sides of semiconductor stripes and islands 151 and 154b and ohmic contacts 161, 163b, 165a and 165b are inclined relative to the surface of the substrate 110, and the inclination angles thereof are preferably in a range of about 30-80 degrees.

A plurality of data conductors including a plurality of data lines 171 including first input electrodes 173a, a plurality of second input electrodes 173b, and a plurality of first and second output electrodes 175a and 175b are formed on ohmic contacts 161, 163b, 165a and 165b and the gate insulating layer 140.

Data lines 171 transmit data voltages and extend substantially in the longitudinal direction to intersect scanning lines 121. Each of data lines 171 also intersects storage electrode lines 131 and runs between adjacent pairs of storage electrodes 133a and 133b. Each data line 171 may include an end portion (not shown) having a large area for contact with another layer or an external driving circuit. Data lines 171 may extend to be connected to a data driver 500 that may be integrated on the substrate 110.

First input electrodes 173a project from data lines 171 toward the first control electrodes 124a and are curved like a character J. First output electrodes 175a are separated from data lines 171 and disposed opposite the first input electrodes 173a with respect to the first control electrodes 124a. Each of first output electrodes 175a includes a wide end portion and a narrow end portion. The wide end portion overlaps a storage electrode line 131 and the narrow end portion is partly enclosed by a first input electrode 173a.

A first control electrode 124a, a first input electrode 173a, and a first output electrode 175a along with a projection 154a of a semiconductor stripe 151 form a TFT for a pixel PX. The TFT has a channel formed in a polycrystalline portion A of the projection 154a disposed between the first input electrode 173a and the first output electrode 175a.

A second control electrode 124b, a second input electrode 173b, and a second output electrode 175b along with a semiconductor island 154b form a TFT for scanning driver 400. The TFT has a channel formed in a polycrystalline portion B of the semiconductor island 154b disposed between the second input electrode 173b and the second output electrode 175b.

Since the channels of the TFTs are formed in the polycrystalline portions A and B, which have high electron mobility, the driving speed of the TFTs is improved. In addition, there are no lightly doped regions in semiconductor stripes and islands 151 and 154b or ohmic contacts 161 which are usually required in a conventional polysilicon TFT to reduce leakage current, 163b, 165a and 165b. Thus the structure of the TFTs is more simple.

Data conductors 171, 173b, 175a and 175b have a triple-layered structure including a lower film 171p, 173bp, 175ap and 175bp, an intermediate film 171q, 173bq, 175aq and 175bq, and an upper film 171r, 173br, 175ar and 175br. The lower film 171p, 173bp, 175ap and 175bp may be made of refractory metal such as Cr, Mo, Ta, Ti, or alloys thereof, the intermediate film 171q, 173bq, 175aq and 175bq may be made of low resistivity metal such as Al containing metal, Au containing metal, and Ni containing metal, and the upper film 171r, 173br, 175ar and 175br may be made of refractory metal or alloys thereof having a good contact characteristic with ITO or IZO. An example of the triple-layered structure is a lower Mo (alloy) film, an intermediate Al (alloy) film, and an upper Mo (alloy) layer.

Data conductors 171, 173b, 175a and 175b may have a double-layered structure including a refractory-metal lower film (not shown) and a low-resistivity upper film (not shown) of Al containing metal, Au containing metal, or Ni containing metal. Otherwise, data conductors 171, 173b, 175a and 175b may have a single-layer structure preferably made of Al containing metal, Au containing metal, or Ni containing metal. However, data conductors 171, 173b, 175a and 175b may be made of various metals or conductors.

In FIGS. 2 and 3, for the first input electrodes 173a, the lower, the intermediate, and the upper films thereof are denoted by additional characters p, q and r, respectively.

The conductor contained in semiconductor stripes 151 and islands 154b may be one of the materials of data conductors 171, 173b, 175a and 175b.

Data conductors 171, 173b, 175a and 175b have inclined edge profiles, and the inclination angles thereof range about 30-80 degrees.

Ohmic contacts 161, 163b, 165a and 165 are interposed only between the underlying semiconductor stripes and islands 151 and 154b and the overlying data conductors 171, 173b, 175a and 175b thereon and reduce the contact resistance therebetween. Although semiconductor stripes 151 are narrower than data lines 171 at most places, the width of semiconductor stripes 151 becomes large near scanning lines 121 and storage electrode lines 131 as described above, to smooth the profile of the surface, thereby preventing the disconnection of data lines 171. Semiconductor stripes and islands 151 and 154b include some exposed portions, which are not covered with data conductors 171, 173b, 175a and 175b, such as portions located between the input electrodes 173a and 173a and the output electrodes 175a and 175b.

A passivation layer 180 is formed on data conductors 171, 173b, 175a and 175b and the exposed portions of semiconductor stripes and islands 151 and 154b. The passivation layer 180 may be made of inorganic or organic insulator and it may have a flat top surface. Examples of the inorganic insulator include silicon nitride and silicon oxide. The organic insulator may have photosensitivity and dielectric constant less than about 4.0. Passivation layer 180 may include a lower film of inorganic insulator and an upper film of organic insulator such that it takes the excellent insulating characteristics of the organic insulator while preventing the exposed portions of semiconductor stripes and islands 151 and 154b from being damaged by the organic insulator.

Passivation layer 180 has a plurality of contact holes 185 exposing first output electrodes 175a. Passivation layer 180 and gate insulating layer 140 have a plurality of contact holes 183 exposing portions of storage electrode lines 131 near the fixed end portions of the second storage electrodes 133b and a plurality of contact holes 184 exposing the linear branches of the free end portions of the second storage electrodes 133b.

A plurality of pixel electrodes 191 and a plurality of overpasses 84 are formed on the passivation layer 180. They may be made of transparent conductor such as ITO or IZO or reflective conductor such as Ag, Al, Cr, or alloys thereof.

Pixel electrodes 191 are physically and electrically connected to first output electrodes 175a through the contact holes 185 such that pixel electrodes 191 receive data voltages from first output electrodes 175a. Pixel electrodes 191 supplied with the data voltages generate electric fields in cooperation with a common electrode 270 of the upper panel 200 supplied with a common voltage Vcom, which determine the orientations of liquid crystal molecules of a liquid crystal layer 3 disposed between the two electrodes. The orientations of the liquid crystal molecules determined the polarization of light passing through the liquid crystal layer 3. A pixel electrode 191 and the common electrode 270 form a liquid crystal capacitor, which stores applied voltages after the TFT turns off.

A pixel electrode 191 and a drain electrode 175 connected thereto overlap a storage electrode line 131 including storage electrodes 133a and 133b to form a storage capacitor which enhances the voltage storing capacity of the liquid crystal capacitor.

Overpasses 84 cross over scanning lines 121 and they are connected to the exposed portions of storage electrode lines 131 and the exposed linear branches of the free end portions of the second storage electrodes 133b through the contact holes 183 and 184, respectively, which are disposed opposite each other with respect to scanning lines 121. Storage electrode lines 131 including the storage electrodes 133a and 133b along with the overpasses 84 can be used for repairing defects in scanning lines 121, data lines 171, or the TFTs.

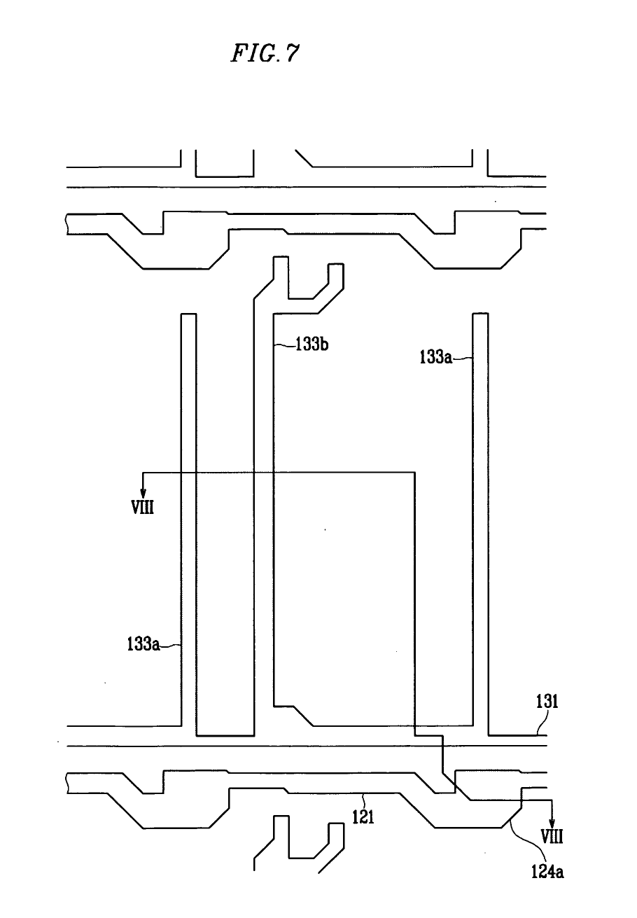

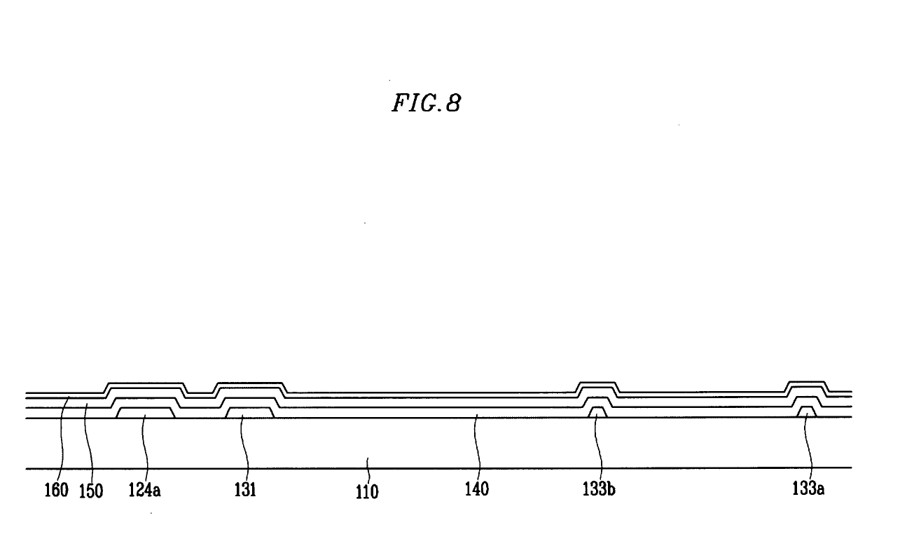

A method for manufacturing the TFT array panel shown in FIGS. 3-6 according to an embodiment of the present invention will be described with reference to FIGS. 7-22 as well as FIGS. 3-6.

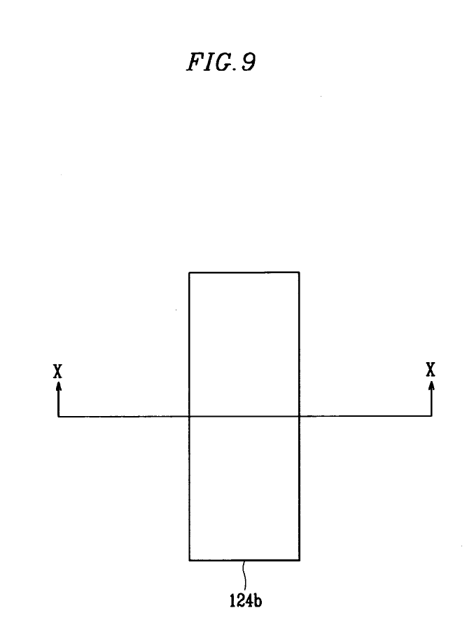

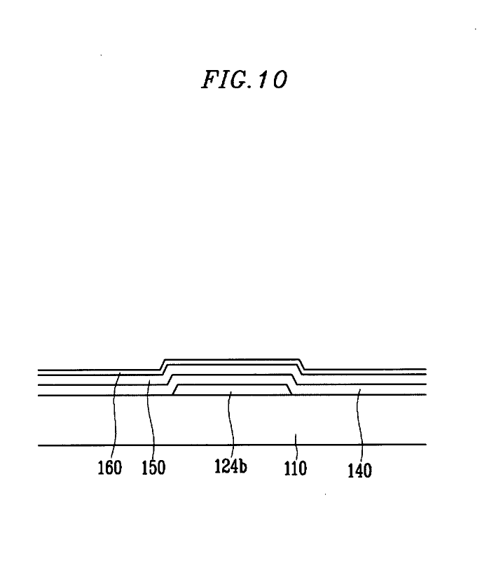

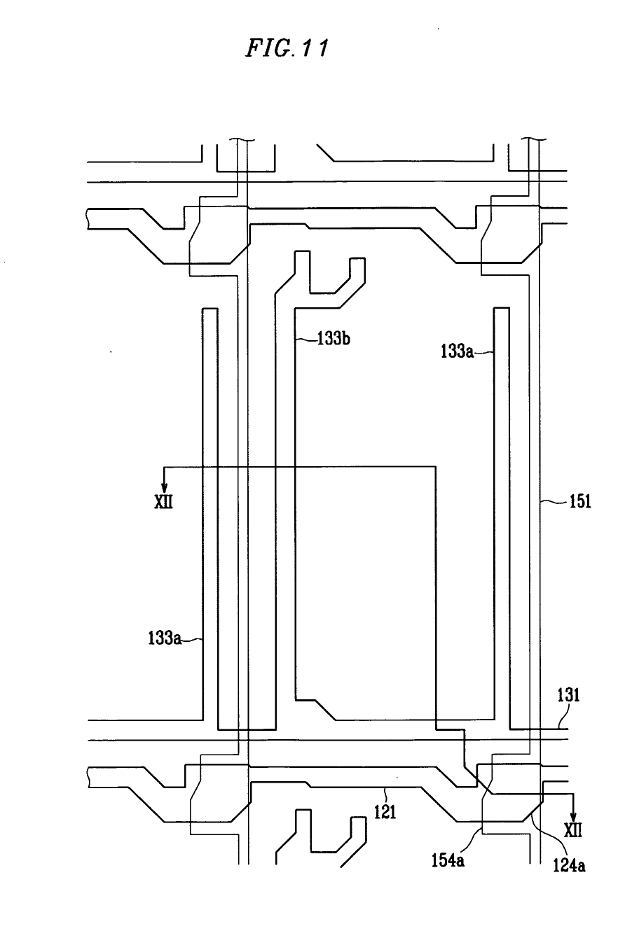

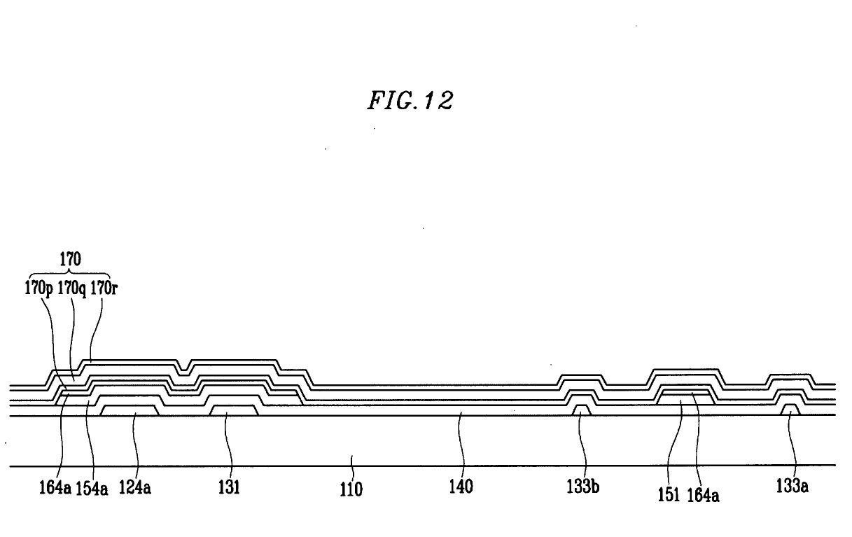

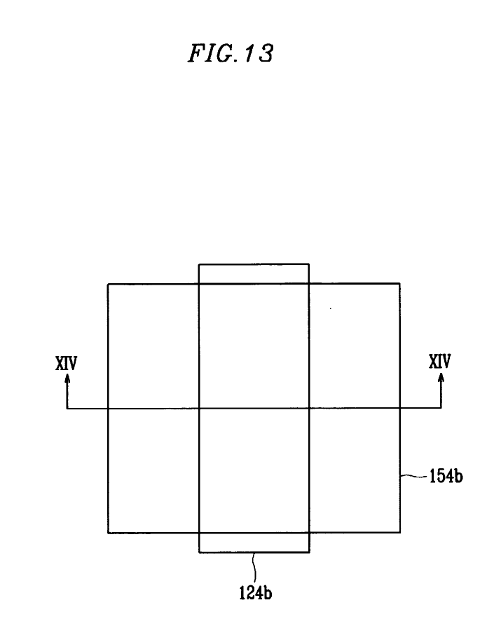

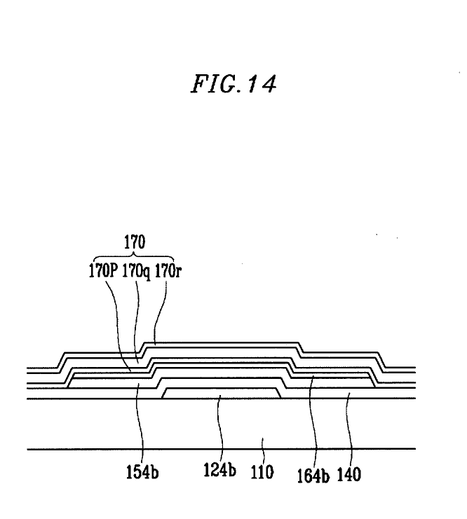

FIGS. 7 and 9 are layout views of the TFT array panel shown in FIGS. 3-6 in the first step of a manufacturing method thereof according to an embodiment of the present invention, and FIGS. 8 and 10 are sectional views of the TFT array panel shown in FIGS. 7 and 9 taken along lines VIII-VIII and X-X, respectively. FIGS. 11 and 13 are layout views of the TFT array panel shown in FIGS. 3-6 in a step following the step shown in FIGS. 7-10, and FIGS. 12 and 14 are sectional views of the TFT array panel shown in FIGS. 11 and 13 taken along lines XII-XII and XIV-XIV, respectively. FIGS. 15 and 17 are layout views of the TFT array panel shown in FIGS. 3-6 in a step following the step shown in FIGS. 11-14, and FIGS. 16 and 18 are sectional views of the TFT array panel shown in FIGS. 15 and 17 taken along lines XVI-XVI and XVIII-XVIII, respectively. FIGS. 19 and 21 are layout views of the TFT array panel shown in FIGS. 3-6 in a step following the step shown in FIGS. 15-18, and FIGS. 20 and 22 are sectional views of the TFT array panel shown in FIGS. 19 and 21 taken along lines XX-XX and XXII-XXII, respectively.

Referring to FIGS. 7-10, a metal layer is deposited on an insulating substrate 110 and patterned to form a plurality of scanning lines 121 including first control electrodes 124a, a plurality of storage electrode lines 131 including storage electrodes 133a and 133b, and a plurality of second control electrodes 124b.

Next, a gate insulating layer 140, an intrinsic a-Si layer 150, and an extrinsic a-Si layer 160 are sequentially deposited by plasma enhanced chemical vapor deposition, etc.

Referring to FIGS. 11-14, the extrinsic a-Si layer 160 and the intrinsic a-Si layer 150 are patterned by lithography and etching to form a plurality of extrinsic semiconductor stripes and islands 164a and 164b, and a plurality of (intrinsic) semiconductor stripes and islands 151 and 154b. Each of semiconductor stripes 151 includes a plurality of projections 154a.

Subsequently, a data metal layer 170 is deposited by sputtering, etc. The metal layer 170 includes a lower film 170p preferably made of a Mo containing metal, an intermediate film 170q preferably made of an Al containing metal, and an upper film 170r preferably made of a Mo containing metal.

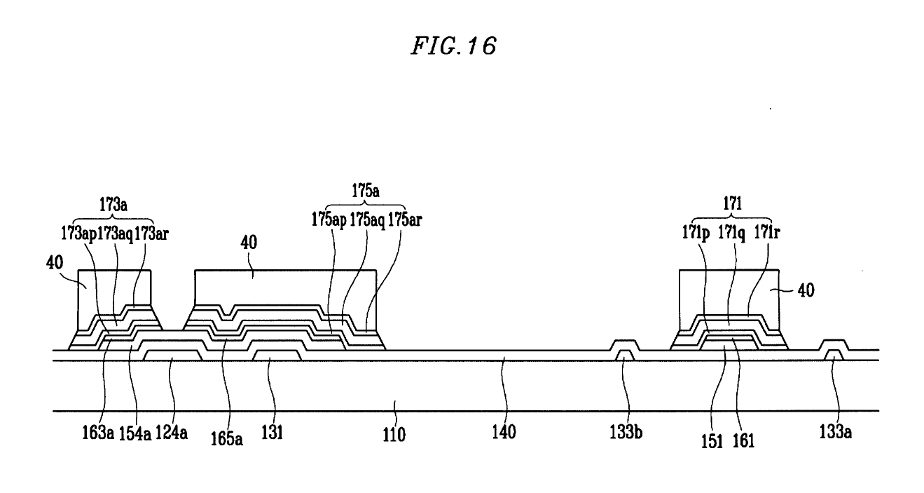

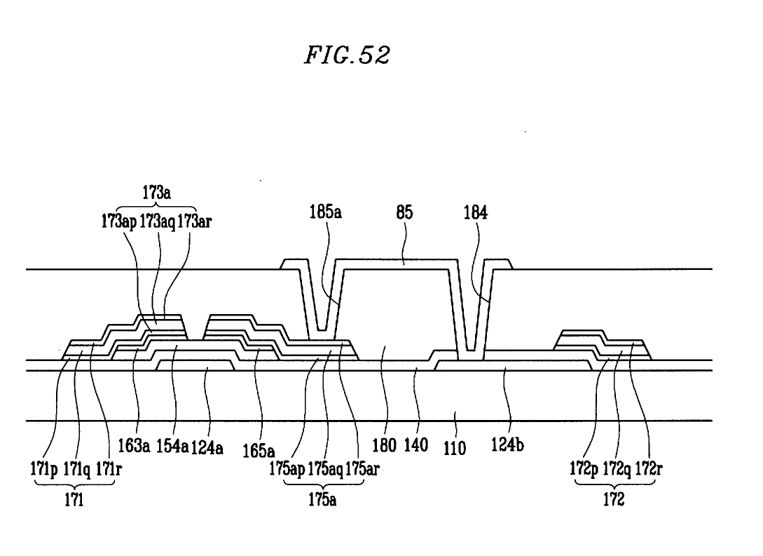

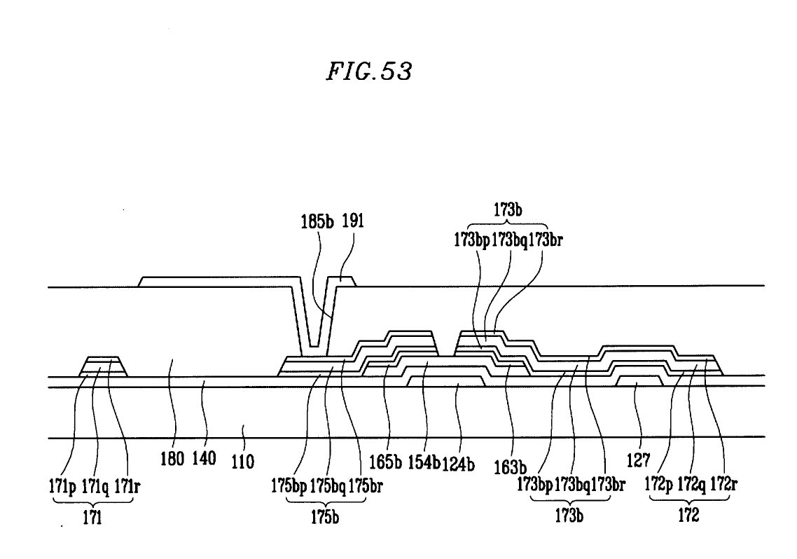

Referring to FIGS. 15-18, a photoresist 40 is formed on the data metal layer 170, and the metal layer 170 is then patterned by lithography and wet etch with the photoresist etch mask 40 to form a plurality of data conductors that include a plurality of data lines 171 including first input electrodes 173a, a plurality of second input electrodes 173b, and a plurality of first and second output electrodes 175a and 175b. In FIGS. 16 and 18, for each of data conductors 171, 173a, 173b, 175a and 175b, the lower, the intermediate, and the upper films thereof are denoted by additional characters p, q and r, respectively.

Thereafter, exposed portions of the extrinsic semiconductor stripes and islands 164a and 164b, which are not covered with data conductors 171, 173b, 175a and 175b, are removed to complete a plurality of ohmic contact stripes 161 including projections 163a and a plurality of ohmic contact islands 163b, 165a and 165b and to expose portions of the intrinsic semiconductor stripes and islands 151 and 154b.

Successively, the photoresist 40 is removed by a photoresist stripper containing butyl diglycol (or diethylene glycol monobutyl ether), diethylene glycol monoethyl ether, dimethyl sulfoxide, N-methylpyrrolidone, and monoisopropanolamine. Among the above-listed materials, dimethyl sulfoxide, N-methylpyrrolidone, and monoisopropanolamine dissolves aluminum in the intermediate films 171q, 173bq, 175aq and 175bq, and the dissolved aluminum flows onto the surface of the exposed portions of semiconductor stripes and islands 151 and 154b to form a thin film. The thickness of the aluminum thin film may be equal to or greater than about 1 nanometer.

Annealing at about 130-400° C. causes the exposed portions of semiconductor stripes and islands 151 and 154b to be crystallized from the surface thereof since the aluminum thin film on the exposed portions of semiconductor stripes and islands 151 and 154b serves as a seed for the crystallization. After the polycrystallization, aluminum may remain in semiconductor stripes and islands 151 and 154b.

Referring to FIGS. 19-22, a photosensitive organic passivation layer 180 is formed and patterned by lithography to form a plurality of contact holes 185 and upper portions of sidewalls of a plurality of contact holes 183 and 184. Thereafter, the gate insulating layer 140 is etched to complete the contact holes 183 and 184.

Finally, a plurality of pixel electrodes 191 and a plurality of overpasses 84 are formed by sputtering and patterning a transparent conductive layer of ITO, etc., as shown FIGS. 3-6.

As described above, since there is no need for laser beam in the crystallization and an impurity implantation step for forming impurity regions such as lightly doped regions is not required, the process steps are simplified.

Data conductors 171, 173b, 175a and 175b may include any conductive material that can be dissolved into a photoresist stripper and can serve as a seed for crystallization.

Another example of a TFT array panel shown in FIG. 2A will be described in detail with reference to FIGS. 23, 24 and 25.

FIG. 23 is a layout view of a TFT array panel according to another embodiment of the present invention, and FIGS. 24 and 25 are sectional views of the TFT array panel shown in FIG. 23 taken along lines XXIV-XXIV and XXV-XXV, respectively.

A TFT array panel according to this embodiment includes neither a scanning driver nor a data driver, and thus it includes no TFT shown in FIGS. 5 and 6. Except for this, a layered structure of the TFT array panel according to this embodiment is almost the same as those shown in FIG. 3 and 4.

That is, a plurality of gate conductors including scanning lines 121 and storage electrode lines 131 are disposed on a substrate 110. Each of scanning lines 121 includes control electrodes 124, and each of storage electrode lines 131 includes first and second storage electrodes 133a and 133b.

A gate insulating layer 140 is disposed on gate conductors 121 and 131 and the substrate 110.

A plurality of semiconductor stripes 151 including projections 154 are disposed on the gate insulating layer 140, and each of semiconductor stripes 151 includes a plurality of polycrystalline portions A and other amorphous portions.

A plurality of ohmic contact stripes 161 including projections 163 and a plurality of ohmic contact islands 165 are disposed on semiconductor stripes 151.

A plurality of data conductors including a plurality of data lines 171 and a plurality of output electrodes 175 are formed on ohmic contacts 161 and 165. Each of data lines 171 includes a plurality of input electrodes 173, and data conductors 171 and 175 cover the amorphous portions of semiconductor stripes 151 but not the polycrystalline portions.

A passivation layer 180 is formed on data conductors 171 and 175, the polycrystalline portions A of semiconductor islands 154, and the gate insulating layer 140. A plurality of contact holes 183, 184 and 185 are provided at the passivation layer 180 and the gate insulating layer 140.

A plurality of pixel electrodes 191 and a plurality of overpasses 84 are formed on the passivation layer 180.

Unlike the TFT array panel shown in FIGS. 3 and 4, semiconductor stripes 151 have almost the same planar shapes as data conductors 171 and 175 as well as the underlying ohmic contacts 161 and 165, except for the polycrystalline portions A exposed out of data conductors 171 and 175.

Each of scanning lines 121 includes an end portion 129 having a large area for contact with scanning driver 400, and each of data lines 171 includes an end portion 179 having a large area for contact with data driver 500. A plurality of contact holes 181 exposing the end portions 129 of scanning lines 121 are formed in the gate insulating layer 140 and the passivation layer 180, and a plurality of contact holes 182 exposing the end portions 179 of data lines 171 are formed in the passivation layer 180.

A plurality of contact assistants 81 connected to the end portions 129 of scanning lines 121 through the contact holes 181 and a plurality of contact assistants 82 connected to the end portions 179 of data lines 171 through the contact holes 182 are formed on the passivation layer 180. The contact assistants 81 and 82 protect the end portions 129 and 179 and enhance the adhesion between the end portions 129 and 179 and terminals of the drivers 400 and 500.

Many of the above-described features of the TFT array panel shown in FIGS. 3 and 4 may be applicable to the TFT array panel shown in FIGS. 23-25.

A method for manufacturing the TFT array panel shown in FIGS. 23-25 according to an embodiment of the present invention will be described with reference to FIGS. 26-38 as well as FIGS. 23-25.

FIG. 26 is a layout view of the TFT array panel shown in FIGS. 23-25 in the first step of a manufacturing method thereof according to an embodiment of the present invention, FIGS. 27 and 28 are sectional views of the TFT array panel shown in FIG. 26 taken along lines XXVII-XXVII and XXVIII-XXVIII, respectively, FIGS. 29 and 30 are sectional views of the TFT array panel shown in FIGS. 26 in a step following the step shown in FIGS. 27 and 28 taken along lines XXVII-XXVII and XXVIII-XXVIII, respectively, and FIGS. 31 and 32 are sectional views of the TFT array panel shown in FIG. 26 in a step following the step shown in FIGS. 29 and 30 taken along lines XXVII-XXVII and XXVIII-XXVIII, respectively. FIG. 33 is a layout view of the TFT array panel shown FIGS. 23-25 in a step following the steps shown in FIGS. 26-32, and FIGS. 34 and 35 are sectional views of the TFT array panel shown in FIG. 33 taken along lines XXXIV-XXXIV and XXXV-XXXV, respectively. FIG. 36 is a layout view of the TFT array panel shown FIGS. 23-25 in a step following the step shown in FIGS. 33-35, and FIGS. 37 and 38 are sectional views of the TFT array panel shown in FIG. 36 taken along lines XXXVII-XXXVII and XXXVIII-XXXVIII, respectively.

Referring to FIGS. 26-28, a metal layer is deposited on an insulating substrate 110 and patterned by lithography and etch to form a plurality of scanning lines 121 including control electrodes 124 and end portions 129 and a plurality of storage electrode lines 131 including storage electrodes 133a and 133b.

Next, a gate insulating layer 140, an intrinsic amorphous (a-Si) silicon layer 150, an extrinsic amorphous silicon layer 160, and a data metal layer 170 are sequentially deposited. The metal layer 170 includes a lower film 170p preferably made of Mo, an intermediate film 170q preferably made of Al, and an upper film 170r preferably made of Mo.

Referring to FIGS. 29 and 30, a photoresist film is coated on the data metal layer 170 and subjected to light exposure and development with a photo mask (not shown) to form a photoresist 50 having a position-dependent thickness. In detail, the photoresist 50 includes a plurality of first portions 52 disposed on wire areas WA and a plurality of second portions 54 thinner than the first portions 52 and disposed on channel areas CA. There is no photoresist on other areas EA.

For descriptive convenience, portions of the data metal layer 170, the extrinsic a-Si layer 160, and the intrinsic a-Si layer 150 on the wire areas WA, on the channel areas, and on the remaining areas EA are referred to as first portions, second portions, and third portions, respectively.

The position-dependent thickness of the photoresist is obtained by several techniques, for example, by providing translucent areas on a photo mask for forming the photoresist as well as light transmitting transparent areas and light blocking opaque areas. The translucent areas may have a slit pattern, a lattice pattern, a thin film(s) with intermediate transmittance or intermediate thickness. When using a slit pattern, it is preferable that the width of the slits or the distance between the slits is smaller than the resolution of a light exposer used for the photolithography. Another example is to use reflowable photoresist. In detail, once a photoresist pattern made of a reflowable material is formed by using a normal photo mask that has only transparent areas and opaque areas, it is subject to reflow process to flow onto areas without the photoresist, thereby forming thin portions.

Referring to FIGS. 31 and 32, the third portions of the data metal layer 170 disposed on the wires areas WA are removed by wet etch using the photoresist 50 as an etch mask to form a plurality of data metal members 174. In FIGS. 31 and 32, for the data metal members 174, the lower, the intermediate, and the upper films thereof are denoted by additional characters p, q and r, respectively.

Thereafter, the third portions of the extrinsic a-Si layer 160 and the intrinsic a-Si layer 150 on the wires areas WA are removed by dry etch to form a plurality of extrinsic semiconductor stripes 164 and a plurality of (intrinsic) semiconductor stripes 151 including projections 154.

Subsequently, the second portions 54 of the photoresist 50 disposed on the channel areas CA are removed by etch back process. At this time, the first portions 52 of the photoresist 50 may be thinned.

Referring to FIGS. 33-35, the data metal members 174 are wet etched by using the first portions 52 of the photoresist 50 to remove the second portions of the data metal members 174 such that each of the data metal members 174 is divided into a plurality of output electrodes 175 and a data line 171 including input electrodes 173 and an end portion 179, and simultaneously, the second portions of the extrinsic semiconductor stripes 164 on the channel areas CA are exposed. In FIGS. 34 and 35, for data lines 171 and the end portions 179 thereof, the input electrodes 173, and the drain electrodes 175, the lower, the intermediate, and the upper films thereof are denoted by additional characters p, q and r, respectively.

The second portions of the extrinsic semiconductor stripes 164 are removed by dry etch such that each of the extrinsic semiconductor stripes 164 is divided into a plurality of ohmic contact islands 165 and an ohmic contact stripe 161 including projections 163 and simultaneously, the second portions of the intrinsic semiconductor stripes 151 on the channel areas CA are exposed.

Successively, the first portions 52 of the photoresist 50 is removed by a photoresist stripper containing butyl diglycol (or diethylene glycol monobutyl ether), diethylene glycol monoethyl ether, dimethyl sulfoxide, N-methylpyrrolidone, and monoisopropanolamine. Among the above-listed materials, dimethyl sulfoxide, N-methylpyrrolidone, and monoisopropanolamine dissolves aluminum in the intermediate films 171q and 175q, and the dissolved aluminum flows onto the surface of the exposed second portions of semiconductor stripes 151 to form a thin film. The thickness of the aluminum thin film may be equal to or greater than about 1 nanometer.

Annealing at about 130-400° C. causes the second portions of semiconductor stripes 151 to be crystallized as described with reference to FIGS. 15-18.

Referring to FIGS. 36-38, a passivation layer 180 is deposited and patterned along with the gate insulating layer 140 to form a plurality of contact holes 181, 182, 183, 184 and 185.

Finally, a plurality of pixel electrodes 191, a plurality of overpasses 84, and a plurality of contact assistants 81 and 82 are formed by sputtering and patterning a transparent conductive layer of ITO or IZO as shown FIGS. 23-25.

As a result, the manufacturing process is simplified by omitting a photolithography step as compared with that shown in FIGS. 7-22.

Many of the above-described features of the manufacturing method shown in FIGS. 7-22 may be applicable to the manufacturing method shown in FIGS. 26-38.

Referring to FIGS. 39, 40 and 41 as well as FIGS. 1 and 2B, an exemplary detailed structure of the panel unit of the OLED display shown in FIG. 2B will be described in detail.

FIG. 39 is a layout view of a panel unit for an OLED display according to an embodiment of the present invention and FIGS. 3 and 4 are sectional views of the panel unit shown in FIG. 39 taken along the lines XL-XL and XLI-XLI, respectively.

A plurality of gate conductors that include a plurality of scanning lines 121 including first control electrodes 124a and a plurality of second control electrodes 124b are formed on an insulating substrate 110 such as transparent glass or plastic.

Scanning lines 121 for transmitting scanning signals extend substantially in a transverse direction. Each scanning line 121 further includes an end portion 129 having a large area for contact with another layer or an external driving circuit, and the first control electrodes 124a project upward from the scanning line 121. Scanning lines 121 may extend to be directly connected to scanning driver 400, which may be integrated on the substrate 110.

Each of the second control electrodes 124b is separated from scanning lines 121 and it includes a storage electrode 127 extending downward from the second control electrode 124b, turning to the right, and extending upward.

Gate conductors 121 and 124b may be made of Al containing metal, Ag containing metal, Cu containing metal, Mo containing metal, Cr, Ta, Ti, etc. Gate conductors 121 and 124b may have a multi-layered structure including two films having different physical characteristics. One of the two films may be made of low resistivity metal including Al containing metal, Ag containing metal, and Cu containing metal for reducing signal delay or voltage drop. The other film may be made of material such as Mo containing metal, Cr, Ta, or Ti, which has good physical, chemical, and electrical contact characteristics with other materials such as ITO or IZO. Good examples of the combination are a lower Cr film and an upper Al (alloy) film and a lower Al (alloy) film and an upper Mo (alloy) film. However, gate conductors 121 and 124b may be made of other various metals or conductors.

The lateral sides of gate conductors 121 and 124b are inclined relative to a surface of the substrate 110, and the inclination angle thereof ranges about 30-80 degrees.

A gate insulating layer 140 that may be made of silicon nitride or silicon oxide is formed on gate conductors 121 and 124b.

A plurality of first and second semiconductor islands 154a and 154b are formed on the gate insulating layer 140. The first and the second semiconductor islands 154a and 154b are disposed on the first and the second control electrodes 124a and 124b, respectively. Semiconductor islands 154a and 154b may be made of hydrogenated a-Si except for portions denoted by reference character A in FIG. 40 and denoted by reference character B in FIG. 41, and the portions A and B may be made of polysilicon.

A plurality of pairs of first ohmic contact islands 163a and 165a and a plurality of pairs of second ohmic contact islands 163b and 165b are formed on the first and the second semiconductor islands 154a and 154b, respectively. Ohmic contacts 163a, 163b, 165a and 165b may be made of silicide or n+ hydrogenated a-Si heavily doped with n type impurity such as phosphorous. The first ohmic contacts 163a and 165a are located in pairs on the first semiconductor islands 154a, and the second ohmic contacts 163b and 165b are located in pairs on the second semiconductor islands 154b.

A plurality of data conductors including a plurality of data lines 171, a plurality of driving voltage lines 172, and a plurality of first and second output electrodes 175a and 175b are formed on ohmic contacts 163a, 163b, 165b and 165b and the gate insulating layer 140.

Data lines 171 for transmitting data signals extend substantially in the longitudinal direction and intersect scanning lines 121. Each data line 171 includes a plurality of first input electrodes 173a extending toward the first control electrodes 124a and an end portion 179 having a large area for contact with another layer or an external driving circuit. Data lines 171 may extend to be directly connected to data driver 500, which may be integrated on the substrate 110.

The driving voltage lines 172 for transmitting driving voltages extend substantially in the longitudinal direction and intersect scanning lines 121. Each driving voltage line 172 includes a plurality of second input electrodes 173b extending toward the second control electrodes 124b. The driving voltage lines 172 overlap the storage electrodes 127 and they may be connected to each other.

The first and the second output electrodes 175a and 175b are separated from each other and from data lines 171 and the driving voltage lines 172. Each pair of the first input electrodes 173a and first output electrodes 175a are disposed opposite each other with respect to a first control electrode 124a, and each pair of the second input electrodes 173b and the second output electrodes 175b are disposed opposite each other with respect to a second control electrode 124b.

Data conductors 171, 172, 175a and 175b have a triple-layered structure including a lower film 171p, 172p, 175ap and 175bp, an intermediate film 171q, 172q, 175aq and 175bq, and an upper film 171r, 172r, 175ar and 175br. The lower film 171p, 172p, 175ap and 175bp may be made of refractory metal such as Cr, Mo, Ta, Ti, or alloys thereof, the intermediate film 171q, 172q, 175aq and 175bq may be made of low resistivity metal such as Al containing metal, Au containing metal, and Ni containing metal, and the upper film 171r, 172r, 175ar and 175br may be made of refractory metal or alloys thereof having a good contact characteristic with ITO or IZO. An example of the triple-layered structure is a lower Mo (alloy) film, an intermediate Al (alloy) film, and an upper Mo (alloy) layer.

In FIGS. 40 and 41, for the end portions 179 of data lines 171 and the first and the second input electrodes 173a and 173b, the lower, the intermediate, and the upper films thereof are denoted by additional characters p, q and r, respectively.

Like gate conductors 121 and 124b, data conductors 171, 172, 175a and 175b have inclined edge profiles, and the inclination angles thereof range about 30-80 degrees.

Ohmic contacts 163a, 163b, 165b and 165b are interposed only between the underlying semiconductor islands 154a and 154b and the overlying data conductors 171, 172, 175a and 175b and reduce the contact resistance therebetween. Semiconductor islands 154a and 154b include a plurality of exposed portions, which are not covered with data conductors 171, 172, 175a and 175b, such as portions disposed between the input electrodes 173a and 173b and the output electrodes 175a and 175b.

A passivation layer 180 is formed on data conductors 171, 172, 175a and 175b and the exposed portions of semiconductor islands 154a and 154b. Passivation layer 180 may be made of inorganic or organic insulator and it may have a flat top surface. Examples of the inorganic insulator include silicon nitride and silicon oxide. The organic insulator may have photosensitivity and dielectric constant less than about 4.0. Passivation layer 180 may include a lower film of inorganic insulator and an upper film of organic insulator such that it takes the excellent insulating characteristics of the organic insulator while preventing the exposed portions of semiconductor islands 154a and 154b from being damaged by the organic insulator.

Passivation layer 180 has a plurality of contact holes 182, 185a and 185b exposing the end portions 179 of data lines 171, first output electrodes 175a, and the second output electrodes 175b, respectively, and the passivation layer 180 and the gate insulating layer 140 have a plurality of contact holes 181 and 184 exposing the end portions 129 of scanning lines 121 and the second control electrodes 124b, respectively.

A plurality of pixel electrodes 191, a plurality of connecting members 85, and a plurality of contact assistants 81 and 82 are formed on passivation layer 180 and may be made of a transparent conductor such as ITO or IZO, or of a reflective conductor such as Al, Ag, or alloys thereof.

Pixel electrodes 191 are connected to the second output electrodes 175b through the contact holes 185b and the connecting members 85 are connected to the second control electrodes 124b and first output electrodes 175a through the contact holes 184 and 185b, respectively.

Contact assistants 81 and 82 are connected to the end portions 129 of scanning lines 121 and the end portions 179 of data lines 171 through the contact holes 181 and 182, respectively. The contact assistants 81 and 82 protect the end portions 129 and 179 and enhance the adhesion between the end portions 129 and 179 and external devices.

A partition 361 is formed on the passivation layer 180. The partition 361 surrounds pixel electrodes 191 like a bank to define openings 365. Partition 361 may be made of organic or inorganic insulating material and may be made of photosensitive material containing black pigment so that a black partition 361 may serve as a light blocking member, simplifying the formation of the partition.

A plurality of light emitting members 370 are formed on pixel electrodes 191 and confined in the openings 365 defined by the partition 361. Each of the light emitting members 370 may be made of organic material uniquely emitting one of primary color lights such as red, green and blue lights. The OLED display displays images by spatially adding the monochromatic primary color lights emitted from the light emitting members 370. However, the light emitting members 370 may emit white light and a plurality of color filters (not shown) may be provided on or under the light emitting members 370.

Each of the light emitting members 370 may have a multilayered structure including an emitting layer (not shown) for emitting light and auxiliary layers (not shown) for improving the efficiency of light emission of the emitting layer. The auxiliary layers may include an electron transport layer (not shown) and a hole transport layer (not shown) for improving the balance of the electrons and holes and an electron injecting layer (not shown) and a hole injecting layer (not shown) for improving the injection of the electrons and holes.

A common electrode 270 is formed on the light emitting members and the partition 361. Common electrode 270 is supplied with the common voltage Vcom and may be made of reflective metal such as Ca, Ba, Mg, Al, Ag, etc., or transparent material such as ITO and IZO.

In the above-described OLED display, a first control electrode 124a connected to a scanning line 121, a first input electrode 153a connected to a data line 171, and a first output electrode 155a along with a first semiconductor island 154a form a switching TFT Qs having a channel formed in the first semiconductor island 154a disposed between the first source electrode 173a and the first drain electrode 175a.

Likewise, a second control electrode 124b connected to a first output electrode 155a, a second input electrode 153b connected to a driving voltage line 172, and a second output electrode 155b connected to a pixel electrode 191 along with a second semiconductor island 154b form a driving TFT Qd having a channel formed in the second semiconductor island 154b disposed between the second source electrode 173b and the second drain electrode 175b.

A pixel electrode 191, a light emitting member 370, and the common electrode 270 form an OLED LD having pixel electrode 191 as an anode and the common electrode 270 as a cathode or vice versa.

The overlapping portions of a storage electrode 127 and a driving voltage line 172 form a storage capacitor Cst.

The OLED display emits the light toward the top or bottom of the substrate 110 to display images. A combination of opaque pixel electrodes 191 and a transparent common electrode 270 is employed to a top emission OLED display that emits light toward the top of the substrate 110, and a combination of transparent pixel electrodes 191 and an opaque common electrode 270 is employed to a bottom emission OLED display that emits light toward the bottom of the substrate 110.

A method for manufacturing the panel unit for an OLED display shown in FIGS. 39-41 according to an embodiment of the present invention will be described with reference to FIGS. 42-53 as well as FIGS. 39-41.

FIG. 42 is a layout view of the panel unit for an OLED display shown in FIGS. 39-41 in the first step of a manufacturing method thereof according to an embodiment of the present invention, and FIGS. 43 and 44 are sectional views of the panel unit shown in FIG. 42 taken along lines XLIII-XLIII and XLIV-XLIV, respectively. FIG. 45 is a layout view of the panel unit shown in FIGS. 39-41 in a step following the step shown in FIGS. 42-44, and FIGS. 46 and 47 are sectional views of the panel unit shown in FIG. 45 taken along lines XLVI-XLVI and XLVII-XLVII, respectively. FIG. 48 is a layout view of the panel unit shown in FIGS. 39-41 in a step following the step shown in FIGS. 45-47, and FIGS. 49 and 50 are sectional views of the panel unit shown in FIG. 48 taken along lines XLIX-XLIX and L-L, respectively. FIG. 51 is a layout view of the panel unit shown in FIGS. 39-41 in a step following the step shown in FIGS. 15-18, and FIGS. 52 and 53 are sectional views of the panel unit shown in FIG. 51 taken along lines LII-LII and LIII-LIII, respectively.

Referring to FIGS. 42-44, a metal layer is deposited on an insulating substrate 110 and patterned to form a plurality of scanning lines 121 including first control electrodes 124a and end portions 129 and a plurality of second control electrodes 124b.

Referring to FIGS. 45-47, a gate insulating layer 140, an intrinsic a-Si layer, and an extrinsic a-Si layer are sequentially deposited by plasma enhanced chemical vapor deposition, etc., and the extrinsic a-Si layer and the intrinsic a-Si layer are patterned by lithography and etching to form a plurality of extrinsic semiconductor islands 164a and 164b and a plurality of (intrinsic) semiconductor islands 154a and 154b.

Subsequently, a data metal layer 170 is deposited by sputtering, etc. The metal layer 170 includes a lower film 170p preferably made of a Mo containing metal, an intermediate film 170q preferably made of an Al containing metal, and an upper film 170r preferably made of a Mo containing metal.

Referring to FIGS. 48-50, a photoresist (not shown) is formed on the data metal layer 170, and the metal layer 170 is then patterned by lithography and wet etch with the photoresist etch mask to form a plurality of data conductors that include a plurality of data lines 171 including first input electrodes 173a and end portions 179, a plurality of driving voltage lines 172 including second input electrodes 173b, and a plurality of first and second output electrodes 175a and 175b. In FIGS. 49 and 50, for each of data conductors 171, 172, 173a, 173b, 175a, 175b and 179, the lower, the intermediate, and the upper films thereof are denoted by additional characters p, q and r, respectively.

Thereafter, exposed portions of the extrinsic semiconductor islands 164a and 164b, which are not covered with data conductors 171, 172, 175a and 175b, are removed to complete a plurality of ohmic contact islands 163a, 163b, 165a and 165b and to expose portions A and B of the intrinsic semiconductor islands 154a and 154b.

Successively, the photoresist is removed by a photoresist stripper containing butyl diglycol (or diethylene glycol monobutyl ether), diethylene glycol monoethyl ether, dimethyl sulfoxide, N-methylpyrrolidone, and monoisopropanolamine. Among the above-listed materials, dimethyl sulfoxide, N-methylpyrrolidone, and monoisopropanolamine dissolves aluminum in the intermediate films 171q, 173bq, 175aq and 175bq, and the dissolved aluminum flows onto the surface of the exposed portions A and B of semiconductor islands 154a and 154b to form a thin film. The thickness of the aluminum thin film may be equal to or greater than about 1 nanometer.

Annealing at about 130-400° C. causes the exposed portions A and B of semiconductor islands 154a and 154b to be crystallized from the surface thereof since the aluminum thin film on the exposed portions A and B of semiconductor islands 154a and 154b serves as a seed for the crystallization.

Referring to FIGS. 51-53, a photosensitive organic passivation layer 180 is formed and patterned by lithography to form a plurality of contact holes 182, 185a and 185b and upper portions of sidewalls of a plurality of contact holes 181 and 184. Thereafter, the gate insulating layer 140 is etched to complete the contact holes 181 and 184.

Successively, a plurality of pixel electrodes 191, a plurality of connecting members 85, and a plurality of contact assistants 81 and 82 are formed by sputtering and patterning a transparent conductive layer of ITO, etc.

Finally, a partition 361 having a plurality of openings 365, a plurality of organic light emitting members 370, and a common electrode 270 are formed in sequence as shown in FIGS. 39-41.

Although preferred embodiments of the present invention have been described in detail hereinabove, it should be clearly understood that many variations and/or modifications of the basic inventive concepts herein taught may appear to those skilled in the present art will still fall within the spirit and scope of the present invention.

What is claimed is:

1. A thin film transistor comprising:
a substrate;
a control electrode disposed on the substrate;
a gate insulating layer disposed on the control electrode;
a semiconductor member disposed on the gate insulating layer, overlapping the control electrode, and comprising a first portion of amorphous silicon and a second portion of polycrystalline silicon;
an input electrode contacting the semiconductor member; and
an output electrode contacting the semiconductor member.

2. The thin film transistor of claim 1, wherein the second portion of the semiconductor member extends between the input electrode and the output electrode.

3. The thin film transistor of claim 2, further comprising a plurality of ohmic contacts interposed between the input electrode and the semiconductor member and between the output electrode and the semiconductor member and comprising amorphous silicon doped with impurity.

4. The thin film transistor of claim 1, wherein the second portion of the semiconductor member comprises a sufficiently low amount of a conductive ingredient.

5. The thin film transistor of claim 4, wherein the conductive ingredient in the second portion of the semiconductor member comprises Al, Ni, or Au.

6. The thin film transistor of claim 4, wherein each of the input electrode and the output electrode comprises the conductive ingredient in the second portion of the semiconductor member.

7. The thin film transistor of claim 1, wherein each of the input electrode and the output electrode comprises a first metal film comprising Al, Ni, or Au.

8. The thin film transistor of claim 7, wherein each of the input electrode and the output electrode further comprises a second metal film disposed under the first metal film.

9. The thin film transistor of claim 8, wherein each of the input electrode and the output electrode further comprises a third metal film disposed on the first metal film.

10. The thin film transistor of claim 9, wherein the second and the third metal films comprise at least one of Mo, Cr, Ta, Ti, and alloys thereof.

11. A display panel comprising:
a substrate;
a scanning line disposed on the substrate and comprising a first control electrode;
a gate insulating layer disposed on the scanning line;
a first semiconductor member disposed on the gate insulating layer and comprising a first portion of amorphous silicon and a second portion of polycrystalline silicon;
a data line contacting the first semiconductor member;
a first output electrode separated from the data line and contacting the first semiconductor member;
a passivation layer disposed on the first semiconductor member; and
a pixel electrode disposed on the passivation layer.

12. The display panel of claim 11, wherein the second portion of the first semiconductor member extends between the data line and the first output electrode.

13. The display panel of claim 12, further comprising a plurality of ohmic contacts interposed between the data line and the first semiconductor member and between the first output electrode and the first semiconductor member and comprising amorphous silicon doped with impurity.

14. The display panel of claim 13, wherein each of the data line and the first output electrode comprises a first metal film comprising Al, Ni, or Au.

15. The display panel of claim 14, wherein each of the data line and the first output electrode further comprises a second metal film disposed under the first metal film.

16. The display panel of claim 15, wherein each of the data line and the first output electrode further comprises a third metal film disposed on the first metal film.

17. The display panel of claim 16, wherein the second and the third metal films comprise at least one of Mo, Cr, Ta, Ti, and alloys thereof.

18. The display panel of claim 11, wherein the first portion of the first semiconductor member has substantially the same shape as the data line and the first output electrode.

19. The display panel of claim 11, wherein the first output electrode is connected to the pixel electrode.

20. The display panel of claim 11, further comprising:
a second control electrode disposed on the substrate;
a second semiconductor member disposed on the gate insulating layer, overlapping the second control electrode, and comprising a first portion of amorphous silicon and a second portion of polycrystalline silicon;
a driving voltage line contacting the second semiconductor member;
a second output electrode contacting the second semiconductor member and connected to the pixel electrode; and
an organic light emitting member disposed on the pixel electrode.

21. The display panel of claim 20, wherein the first output electrode and the second control electrode are electrically coupled to each other.

22. A method of manufacturing a thin film transistor, the method comprising:
forming a control electrode on a substrate;
forming a gate insulating layer on the control electrode;
sequentially forming an intrinsic semiconductor member and an extrinsic semiconductor member on the gate insulating layer;
depositing a conductive layer on the extrinsic semiconductor member and the gate insulating layer;
forming a photoresist on the conductive layer;
etching the conductive layer and the extrinsic semiconductor member by using the photoresist as an etch mask to form an input electrode, an output electrode, and ohmic contacts and to expose a portions of the intrinsic semiconductor member;
removing the photoresist by a stripper to form a metal thin film on the exposed portion of the semiconductor member; and
annealing the substrate to crystallize the exposed portion of the semiconductor member.

23. The method of claim 22, wherein the conductive layer comprises a material that is soluble into the stripper for the photoresist.

24. The method of claim 23, wherein the metal thin film is formed by deposition of material dissolved from the conductive layer by the stripper.

25. The method of claim 22, wherein the conductive layer comprises a material that can serve as a seed for the crystallization.

26. The method of claim 22, wherein the crystallization comprises metal induced crystallization with a seed of the metal thin film.

27. The method of claim 22, wherein the annealing is performed at about 130-400° C.

28. The method of claim 22, wherein the conductive layer comprises a first metal film comprising Al, Ni, or Au.

29. The method of claim 28, wherein the conductive layer further comprises:
a second metal film disposed under the first metal film; and
a third metal film disposed on the first metal film.

30. The method of claim 29, wherein the second and the third metal films comprise at least one of Mo, Cr, Ta, Ti, and alloys thereof.

31. The method of claim 22, wherein the stripper comprises butyl diglycol (or diethylene glycol monobutyl ether), diethylene glycol monoethyl ether, dimethyl sulfoxide, N-methylpyrrolidone, and monoisopropanolamine.
